(19) United States
(12) Patent Application Publication
(10) Pub. No.: US 2025/0185231 A1
(43) Pub. Date: Jun. 5, 2025

(54) SEMICONDUCTOR DEVICE AND METHOD FOR FABRICATING THE SAME

(71) Applicant: SK hynix Inc., Gyeonggi-do (KR)

(72) Inventors: Jeong Hoon KWON, Gyeonggi-do (KR); Dong Il SONG, Gyeonggi-do (KR); Kang Sik CHOI, Gyeonggi-do (KR)

(21) Appl. No.: 18/964,685

(22) Filed: Dec. 2, 2024

(30) Foreign Application Priority Data
Dec. 1, 2023 (KR) 10-2023-0172381
Nov. 29, 2024 (KR) 10-2024-0175044

(51) Int. Cl. H10B 12/00

(52) U.S. Cl. CPC H10B 12/30; H10B 12/05

(57) ABSTRACT

A semiconductor device includes a horizontal arrangement of switching elements including nano sheets, horizontal conductive lines, vertical conductive lines, and data storage elements. The horizontal conductive lines surround the nano sheets. Each of the vertical conductive lines is coupled to a corresponding one of first edges of the nano sheets in the horizontal arrangement. Each of the data storage elements is coupled to a corresponding one of second edges of the nano sheets in the horizontal arrangement. The semiconductor device further includes supporters, a first spacer, and a second spacer. The supporters are disposed between the vertical conductive lines. The first spacer has a single layer structure disposed between the data storage elements and the horizontal conductive lines and surrounding the nano sheets. The second spacer has a multi-layer structure disposed between the vertical conductive lines and the horizontal conductive lines and surrounding the nano sheets.

### CROSS-REFERENCE TO RELATED APPLICATIONS

The present application claims priority under 35 U.S.C 119 (a) to Korean Patent Application No. 10-2023-0172381 and No 10-2024-0175044, respectively filed on Dec. 1, 2023, and Nov. 29, 2024, in the Korean Intellectual Property Office, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to satisfy the demand for large capacity and miniaturized memory devices, a three-dimensional (3D) memory device has been proposed in which a plurality of memory cells are arranged in a stacked configuration.

### SUMMARY

Embodiments of the present disclosure are directed to a semiconductor device including high-integrated memory cells, and a method for fabricating the semiconductor device.

In accordance with an embodiment of the present disclosure, a semiconductor device may include: a horizontal arrangement of switching elements (or switches) including nano sheets and horizontal conductive lines surrounding the nano sheets; vertical conductive lines each coupled to a different one of first edges of the nano sheets in the horizontal arrangement; data storage elements (or data storage devices) each coupled to a different one of second edges of the nano sheets in the horizontal arrangement; supporters disposed between the vertical conductive lines; a plurality of first spacers having a single layer structure disposed between the data storage elements and the horizontal conductive lines and surrounding the nano sheets; and a plurality of second spacers having a multi-layer structure disposed between the vertical conductive lines and the horizontal conductive lines and surrounding the nano sheets.

In accordance with an embodiment of the present disclosure, a method for fabricating a semiconductor device may include: forming a stopper layer over a substrate; forming horizontal and vertical arrangements of narrow sheets over the stopper layer; forming a first spacer surrounding first portions of the narrow sheets in the horizontal arrangement; forming horizontal conductive lines surrounding second portions of the narrow sheets in the horizontal arrangement; forming a second spacer surrounding third portions of the narrow sheets in the horizontal arrangement; forming supporters between the narrow sheets in the horizontal arrangement; recessing the narrow sheets in the horizontal arrangement and forming pillar-shaped openings vertically oriented between the supporters; and forming vertical conductive lines in the pillar-shaped openings.

In accordance with an embodiment of the present disclosure, a semiconductor device may include: a substrate; a memory cell array including horizontal and vertical arrangements of nano sheet transistors and vertical conductive lines each coupled to a different one of the nano sheet transistors in the horizontal arrangement and coupled in common to the nano sheet transistors in the vertical arrangement; a stopper layer formed between the memory cell array and the substrate; and supporters disposed between the vertical conductive lines.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A according to an embodiment of the present disclosure.

FIG. 2A is a schematic perspective view illustrating a semiconductor device in accordance with an embodiment of the present disclosure.

FIG. 2B is a partial perspective view illustrating a first tier illustrated in FIG. 2A according to an embodiment of the present disclosure.

FIG. 2C is a partial perspective view illustrating a second conductive line illustrated in FIG. 2A according to an embodiment of the present disclosure.

FIG. 2D is a partial perspective view illustrating a first spacer illustrated in FIG. 2A according to an embodiment of the present disclosure.

FIGS. 2E and 2F are partial perspective views illustrating a second spacer illustrated in FIG. 2A according to an embodiment of the present disclosure.

FIG. 3A is a schematic perspective view illustrating a semiconductor device in accordance with an embodiment of the present disclosure.

FIG. 3B is a schematic plan view illustrating a semiconductor device in accordance with an embodiment of the present disclosure.

FIG. 4A is a schematic cross-sectional view of the semiconductor device taken along line A-A′ illustrated in FIG. 3B according to an embodiment of the present disclosure.

FIG. 4B is a schematic cross-sectional view of the semiconductor device taken along line A1-A1′ illustrated in FIG. 3B an embodiment of the present disclosure.

FIG. 4C is a schematic cross-sectional view of the semiconductor device taken along line B1-B1′ illustrated in FIG. 3B according to an embodiment of the present disclosure.

FIG. 4D is a schematic cross-sectional view of the semiconductor device taken along line B-B′ illustrated in FIG. 3B.

FIGS. 5A to 30B illustrate various operations of a method for fabricating the semiconductor device in accordance with an embodiment of the present disclosure.

FIGS. 31A and 31B are schematic cross-sectional views of a semiconductor device in accordance with embodiments of the present disclosure.

FIGS. 32A and 32B illustrate various views illustrating a stack assembly in accordance with embodiments of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

The following embodiments relate to three-dimensional memory cells, in which memory cells are vertically stacked so as to increase memory cell density and reduce parasitic capacitance.

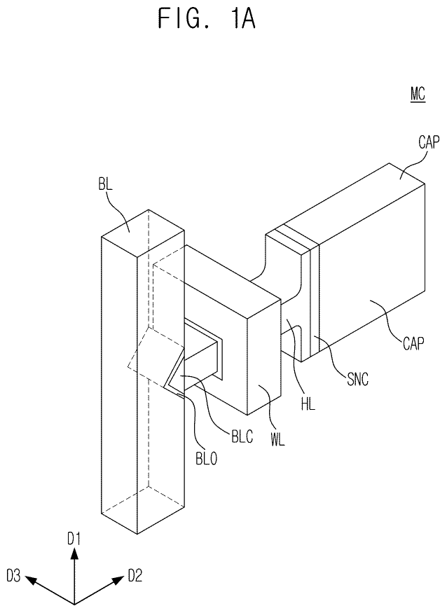

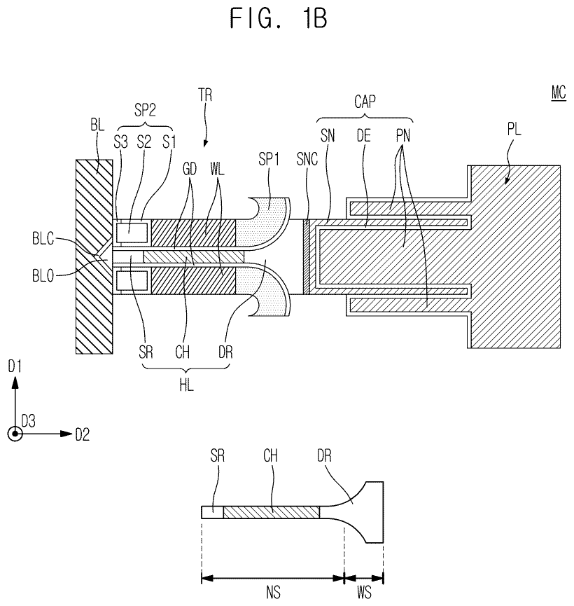

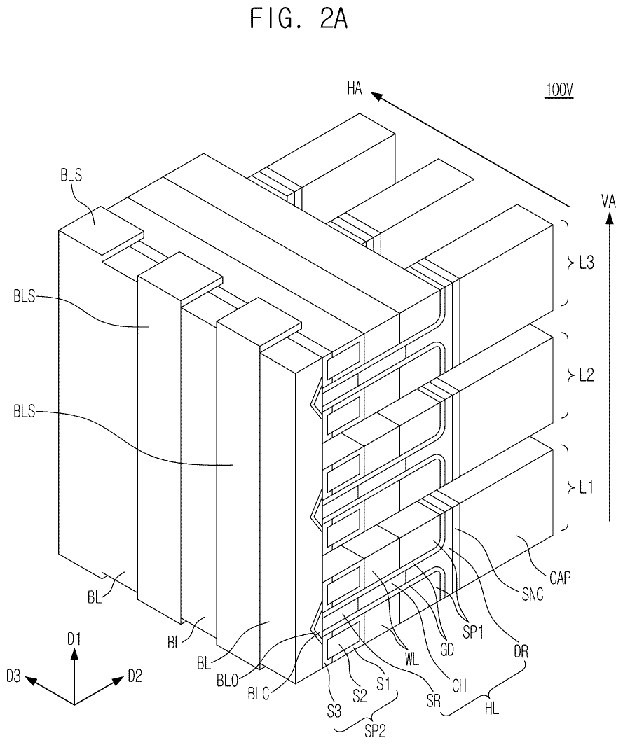

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP. The first conductive line BL may be vertically oriented in a first direction D1. The first conductive line BL may include a bit line. The first conductive line BL may be referred to as a “vertical conductive line”, a “vertically-oriented bit line”, a “vertical-extending bit line”, or a “pillar-shaped bit line”.

The first conductive line BL may include a conductive material. For example, the first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten stack (TiN/W) in which titanium nitride and tungsten are sequentially stacked.

The switching element (or switch) TR performs a function of controlling voltage or current supply to the data storage element CAP during a data write operation and a data read operation performed onto the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. As shown in FIG. 1B, the second conductive line WL completely surrounds the nano sheet HL and therefore, in one embodiment, may be configured as a gate-all-around electrode (GAA). The switching element TR may also be referred to as a “nano sheet transistor”, an “access element” or a “selection element”. The second conductive line WL may be referred to as a “horizontal gate electrode” or a “horizontal word line”

The nano sheet HL may extend in a second direction D2 that intersects with the first direction D1. The second conductive line WL may extend in a third direction D3 that intersects with the first direction D1 and the second direction D2. The first direction D1 may be a vertical direction, and the second direction D2 may be a first horizontal direction, and the third direction D3 may be a second horizontal direction. The nano sheet HL may extend in the first horizontal direction, i.e., the second direction D2, and the second conductive line WL may extend in the second horizontal direction, i.e., the third direction D3. The nano sheet HL may be referred to as a “horizontal layer”.

Referring to FIG. 1B, the nano sheet HL may include a channel CH, a first doped region SR between the channel CH and the first conductive line BL, and a second doped region DR between the channel CH and the data storage element CAP. The first doped region SR and the second doped region DR may have different thicknesses and lengths and cross-sectional shapes. The first doped region SR may be coupled to the first conductive line BL, and the second doped region DR may be coupled to the data storage element CAP. A height (or thickness) of the second doped region DR in the first direction D1 may be greater than a height (or thickness) of the channel CH in the first direction D1. A length of the second doped region DR in the second direction D2 may be less than a length of the channel CH in the second direction D2. In one embodiment, the lengths of the first doped region SR, the channel CH and the second doped region DR in the third direction D3 may be equal to one another.

The nano sheet HL may include a first region NS and a second region WS that are horizontally disposed in the second direction D2. The second region WS may extend from the first region NS. The second region WS may have a thickness that gradually increases (with diverging upper and lower surfaces) in the second direction D2. The second region WS extends from the first region NS toward the data storage element CAP, and thus is disposed between the first region NS and the data storage element CAP. An average vertical height or thickness of the second region WS in the first direction D1 may be greater than an average vertical height or thickness of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape, but may have a different shape (with angled or curved surfaces) in another embodiment. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a flat shape or a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend from the narrow sheet NS. The second doped region DR may include a thick portion disposed in the wide sheet WS at a location adjacent to the data storage element CAP and a thin portion disposed adjacent to the narrow sheet NS. One side of the wide sheet WS and one side of the second doped region DR, which are in contact with the data storage element CAP, may each have a flat side shape.

A horizontal length of the wide sheet WS in the second direction D2 may be less than a horizontal length of the narrow sheet NS. The narrow sheet NS may be referred to as a “long sheet”, and the wide sheet WS may be referred to as a “short sheet”.

The nano sheet HL may include a semiconductor material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, MoS₂, WS₂, or MoSe₂.

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with the same conductivity type of an impurity. Each of the first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be coupled to the first conductive (bit) line BL, and the second doped region DR may be coupled to the data storage element CAP. The first and second doped regions SR and DR may be referred to as “first and second source/drain regions,” e.g., the first doped region SR may correspond to one of a source region or a drain region and the second doped region DR may correspond to the other one of the source region or the drain region.

The nano sheet HL may be horizontally oriented in the second direction D2 from the first conductive line BL.

The second conductive line WL may serve as a gate electrode of the transistor TR and may have a gate-all-around structure (GAA). For example, the second conductive line WL may surround the nano sheet HL and extend in the third direction D3. The nano sheet dielectric layer GD may be formed between the nano sheet HL and the second conductive line WL. The nano sheet dielectric layer GD may also surround the nano sheet HL. The second conductive line WL may surround the nano sheet HL on the nano sheet dielectric layer GD.

The second conductive line WL may include a metal-based material, a semiconductor material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or less, and the P-type work function material may have a high work function of approximately 4.5 eV or greater. The second conductive line WL may include a stack of a low work function material and a high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HON, HfSiO, HfSiON, HfZrO, or a combination thereof. The nano sheet dielectric layer GD may be formed by a thermal oxidation process of a semiconductor material.

The data storage element (or data storage device) CAP may include a memory element such as a capacitor. The data storage element CAP may be horizontally disposed in the second direction D2 adjacent to the switching element TR. The data storage element CAP may include a first electrode SN, a second electrode PN on the first electrode SN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2.

The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first electrode SN may have a three-dimensional structure, which may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces of the first electrode SN.

In some embodiments, the first electrode SN may have a shape different from a cylindrical shape, e.g., may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum nitride (MoN), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium nitride/titanium silicon nitride (TIN/TiSiN) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer. In some embodiments, the dielectric layer DE may be formed of hafnium (Hf)-based oxide.

The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material.

The dielectric layer DE may include silicon oxide (SiO₂) as a high band gap material other than aluminum oxide (Al₂O₃). Because the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material, and have a laminated structure or an intermixed structure. According to the laminated structure, a plurality of high-k materials and a plurality of high band gap materials are stacked. According to the intermixed structure, a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material or other data storage device. For example, the data storage element may be a thyristor, or the data storage material may be or include a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductor material. For example, the first contact node BLC may include titanium, titanium nitride, tungsten, or a combination thereof. In addition, the first contact node BLC may include doped polysilicon, and the first doped region SR may include an impurity diffused from the first contact node BLC.

The second contact node SNC may be disposed between the nano sheet HL and the first electrode SN. The second contact node SNC may include a metal-based material or a semiconductor material. For example, the second contact node SNC may include titanium, titanium nitride, tungsten, or a combination thereof. In addition, the second contact node SNC may include doped polysilicon, and the second doped region DR may include an impurity diffused from the second contact node SNC. A height of the first contact node BLC in the first direction D1 may be less than a height of the second contact node SNC in the first direction D1. For example, the height of the second contact node SNC may be substantially the same as the height of the first electrode SN of the data storage element CAP. The height of the first contact node BLC in the first direction D1 may be greater than a height of the channel CH in the first direction D1. The first and second contact nodes BLC and SNC may each include phosphorus-doped polysilicon or arsenic-doped polysilicon.

The first contact node BLC may be selectively grown from the narrow sheet NS of the nano sheet HL. The first contact node BLC may be formed by selective epitaxial growth (SEG). For example, the first contact node BLC may be a silicon epitaxial layer formed by the SEG. The first contact node BLC may be a doped silicon epitaxial layer. The second contact node SNC may be selectively grown from the wide sheet WS of the nano sheet HL. The second contact node SNC may be formed by the SEG. For example, the second contact node SNC may be a silicon epitaxial layer formed by the SEG. The second contact node SNC may be a doped silicon epitaxial layer.

The first contact node BLC may be a narrow sheet-side contact node, and the second contact node SNC may be a wide sheet-side contact node.

The nano sheet HL may include a first edge and a second edge. The first edge may refer to a portion of the first doped region SR electrically coupled to the first conductive line BL through the first contact node BLC, and the second edge may refer to a portion of the second doped region DR electrically coupled to the first electrode SN of the data storage element CAP through the second contact node SNC.

The memory cell MC may further include an ohmic contact layer BLO between the first contact node BLC and the first conductive line BL. The ohmic contact layer BLO may include metal silicide, such as titanium silicide or molybdenum silicide.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a first sub-spacer S1, a second sub-spacer S2, and a third sub-spacer S3. The second sub-spacer S2 may be disposed between the first sub-spacer S1 and the third sub-spacer S3. The first and second spacers SP1 and SP2 may each include a dielectric material. The first and second spacers SP1 and SP2 may each include silicon oxide, silicon nitride, or a combination thereof. The first spacer SP1 may include silicon nitride. The first and third sub-spacers S1 and S3 of the second spacer SP2 may be silicon nitride, and the second sub-spacer S2 may be silicon oxide. In one embodiment, the first and third sub-spacers S1 and S3 may cover the second sub-spacer S3.

The first spacer SP1 may surround a first portion of the nano sheet HL, e.g., may surround an area overlapping the second doped region DR and at least a portion of the channel CH. The second conductive line WL may surround a second portion of the nano sheet HL overlapping the channel CH. The second spacer SP2 may surround a third portion of the nano sheet HL overlapping the first doped region SR. The first portion, the second portion and the third portion of the nano sheet HL may be defined in the narrow sheet NS.

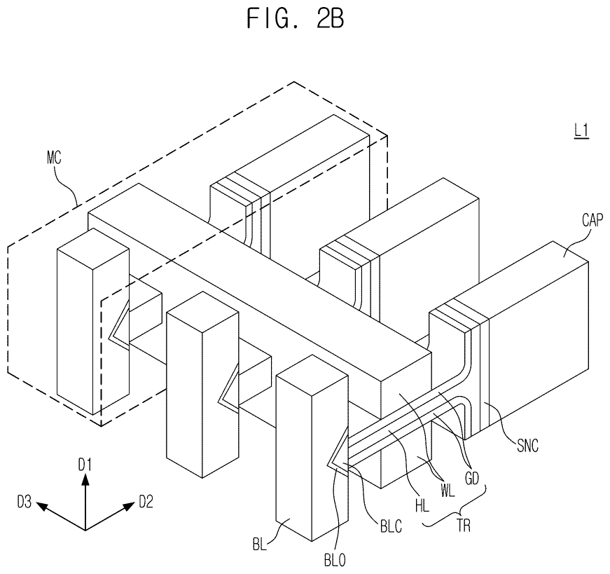

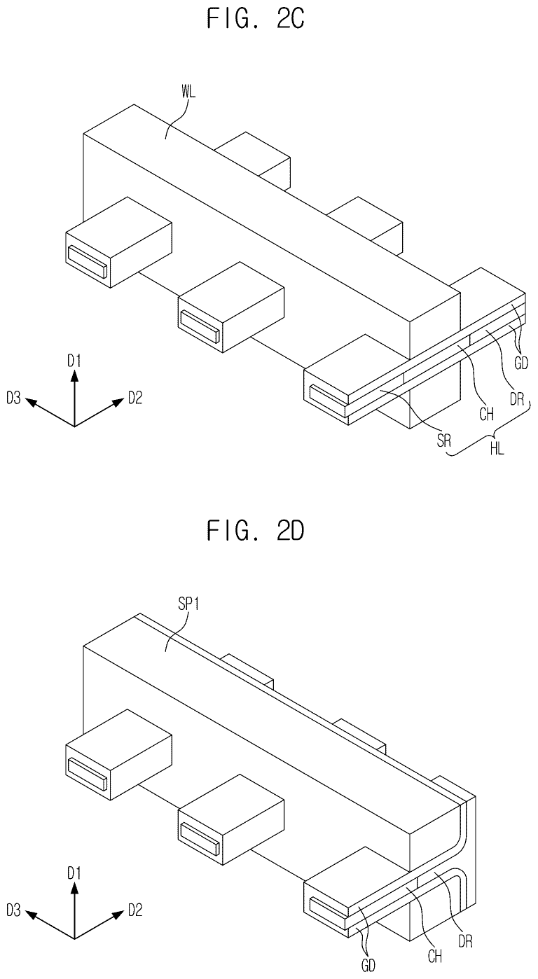

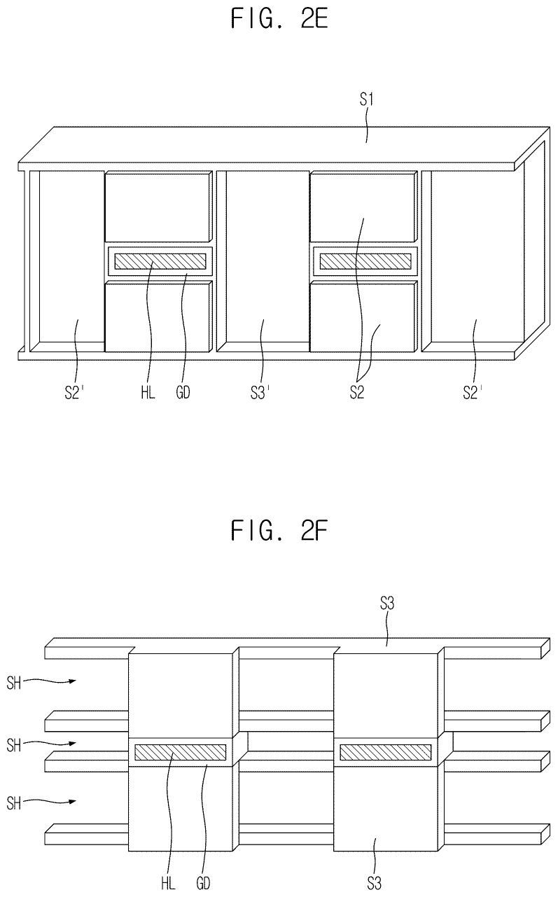

FIG. 2A is a schematic perspective view illustrating a semiconductor device 100V in accordance with an embodiment of the present disclosure. FIG. 2B is a partial perspective view illustrating a first tier L1 illustrated in FIG. 2A. FIG. 2C is a partial perspective view illustrating a second conductive line WL illustrated in FIG. 2A. FIG. 2D is a partial perspective view illustrating a first spacer SP1 illustrated in FIG. 2A. FIGS. 2E and 2F are partial perspective views illustrating a second spacer SP2 illustrated in FIG. 2A.

Referring to FIGS. 2A to 2F, the semiconductor device 100V may include a three-dimensional array of memory cells MC. A detailed description of the memory cells MC are provided above with reference to FIGS. 1A and 1B.

The semiconductor device 100V may include horizontal arrangements HA and vertical arrangements VA of the memory cells MC. Each memory cell MC may have the structure shown in FIGS. 1A and 1B. In each of the horizontal arrangements HA, the memory cells MC may be horizontally spaced apart in a third direction D3. In each of the vertical arrangements VA, the memory cells MC may be vertically stacked in a first direction D1. The memory cells MC in the horizontal arrangements HA may be vertically stacked in the first direction D1. A stack of the horizontal arrangements HA may include a stack of the vertical arrangements VA. The memory cells MC in each of the horizontal arrangements HA may be coupled to different first conductive lines BL and share one second conductive line WL. The memory cells MC in each of the vertical arrangements VA may share different second conductive lines WL and may be coupled to one first conductive line BL.

Each of the vertical arrangements VA may include a plurality of tiers L1, L2 and L3. For example, the vertical arrangement VA of the semiconductor device 100V may have a first tier L1, a second tier L2 and a third tier L3 that are sequentially and vertically stacked. The semiconductor device 100V may have a different number of tiers in another embodiment.

Each of the memory cells MC may include the first conductive line BL, a nano sheet HL, and a data storage element CAP. The nano sheet HL may include a first doped region SR, a channel CH, and a second doped region DR. A first contact node BLC and an ohmic contact layer BLO may be formed between the first doped region SR of the nano sheet HL and the first conductive line BL. A second contact node SNC may be formed between the second doped region DR of the nano sheet HL and the data storage element CAP. The nano sheet HL may be surrounded by a nano sheet dielectric layer GD. The second conductive line WL may extend in the third direction D3 while surrounding the channel CH of the nano sheet HL on the nano sheet dielectric layer GD. The memory cells MC may further include a first spacer SP1 and a second spacer SP2. The first spacer SP1 may have a single layer structure, and the second spacer SP2 may have a multi-layer structure. The second spacer SP2 may include a first sub-spacer S1, a second sub-spacer S2, and a third sub-spacer S3. The second sub-spacer S2 disposed between or coupled to (e.g., and in contact with) the first sub-spacer S1 and the third sub-spacer S3.

The first spacer SP1 may surround first portions of the nano sheets HL in the horizontal arrangement HA, the second conductive line WL may surround second portions of the nano sheets HL in the horizontal arrangement HA, and the second spacer SP2 may surround third portions of the nano sheets HL in the horizontal arrangement HA.

More specifically, the first spacer SP1 may extend in the third direction D3 while surrounding the nano sheets HL in the horizontal arrangement HA. The second spacer SP2 may extend in the third direction D3 while surrounding the nano sheets HL in the horizontal arrangement HA. In detail, the first spacer SP1 may extend in the third direction D3 while surrounding the second doped regions DR in the horizontal arrangement HA. The second spacer SP2 may extend in the third direction D3 while surrounding the first doped regions SR in the horizontal arrangement HA. The second conductive lines WL may extend in the third direction D3 while surrounding the channels CH of the nano sheets HL in the horizontal arrangement HA. In this way, the second conductive lines WL, the first spacers SP1 and the second spacers SP2 may surround the nano sheets HL disposed at the same horizontal level.

The semiconductor device 100V may further include a plurality of supporters BLS, and each of the supporters BLS may be disposed between adjacent ones of the first conductive lines BL in the third direction D3. Upper portions of the supporters BLS may extend to cover (e.g., at least partially overlap) a portion of the second spacer SP2. The first conductive lines BL may be supported by the supporters BLS. The supporters BLS may vertically extend in the first direction D1. The supporters BLS may each include a dielectric material. The first conductive lines BL may be self-aligned with the supporters BLS and the second spacer SP2, and the supporters BLS may be vertically oriented in an extending direction of the first conductive lines BL. The supporters BLS may each include a low-k material, silicon carbon oxide, silicon nitride, an air gap, or a combination thereof.

Referring back to FIGS. 2E and 2F, the second spacer SP2 may include the first sub-spacer S1, the third sub-spacer S3, and the second sub-spacer S2 between or coupled to (e.g., in contact with) the first sub-spacer S1 and the third sub-spacer S3. In one embodiment, the second spacer SP2 may include a combination of one first sub-spacer S1 and a pair of third sub-spacers S3.

The first sub-spacer S1 may have an integral structure, which surrounds the nano sheet HL on the nano sheet dielectric layer GD. The first sub-spacer S1 may include a plurality of recessed portions, and the second sub-spacer S2 and a fourth sub-spacer S2′ may be filled in the recessed portions. The second sub-spacer S2 may have a protruding structure, which vertically faces the nano sheet HL. The fourth sub-spacer S2′ may have a recessed structure, which is disposed in a horizontal space between the nano sheets HL. The fourth sub-spacers S2′ may correspond to a portion of the second sub-spacer S2.

The third sub-spacer S3 may be disposed on upper and lower portions of the nano sheet HL on the nano sheet dielectric layer GD. The third sub-spacer S3 may include a plurality of horizontal holes SH. Portions of the supporters BLS may be filled in the horizontal holes SH.

Referring back to FIGS. 2A and 2E, the second spacer SP2 may extend in the third direction D3 while surrounding portions of the nano sheets HL, i.e., the first doped regions SR.

As described above, the first sub-spacer S1 may surround the third portions of the nano-sheets HL while contacting the second conductive line WL, and in one embodiment the pair of third sub-spacers S3 may contact the first sub-spacer S1 and a corresponding one of the first conductive lines BL. The second sub-spacer S2 may be disposed between or coupled to (e.g., in contact with) the first sub-spacer S1 and the third sub-spacer S3 and may be disposed between the nano sheets HL in the vertical arrangement VA. The fourth sub-spacer S2′ may be disposed between the first sub-spacer S1 and the third sub-spacer S3 and may be disposed between the nano sheets HL in the horizontal arrangement HA.

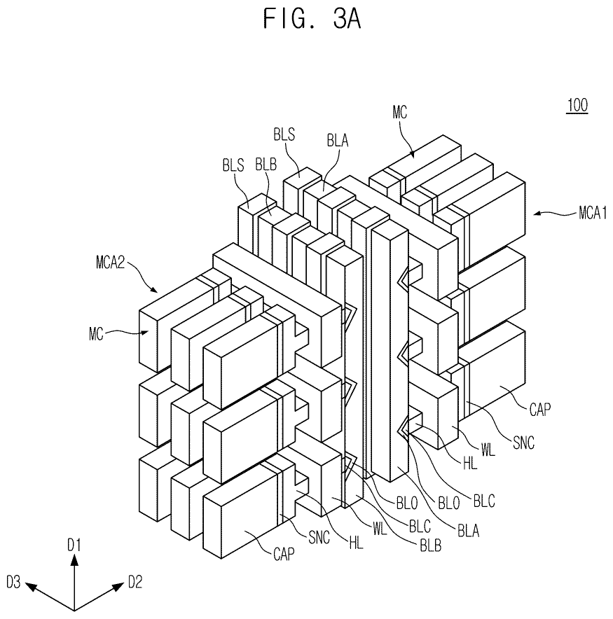

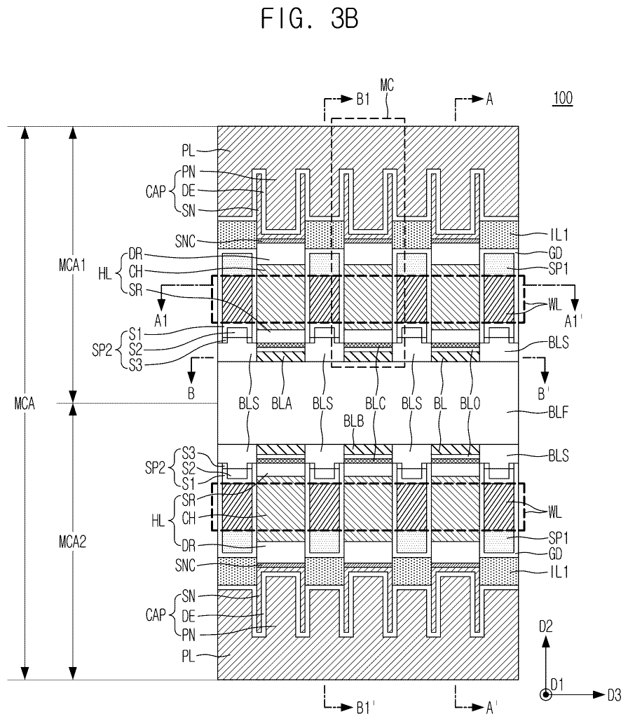

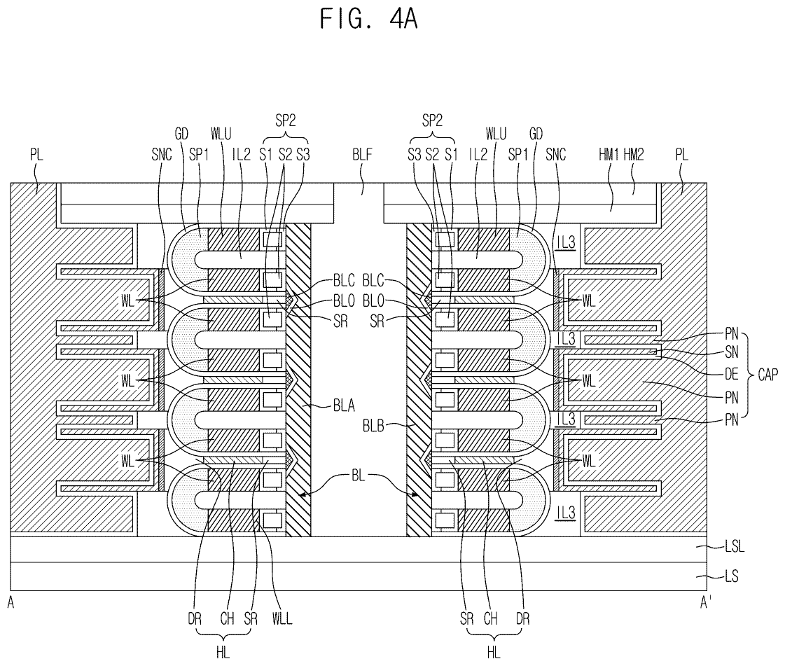

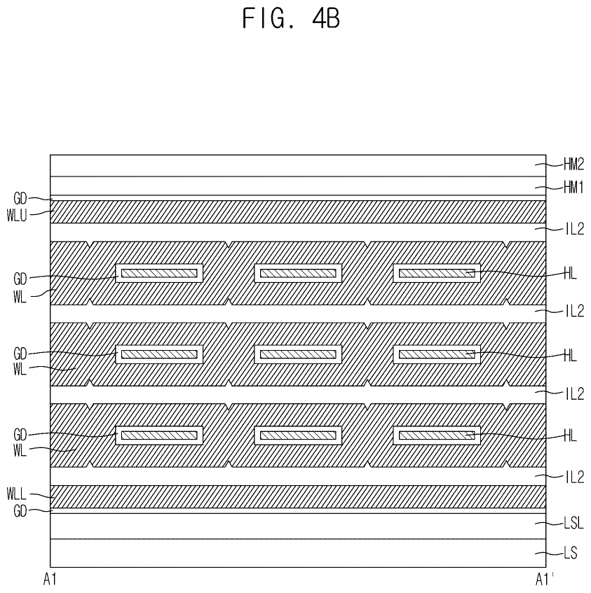

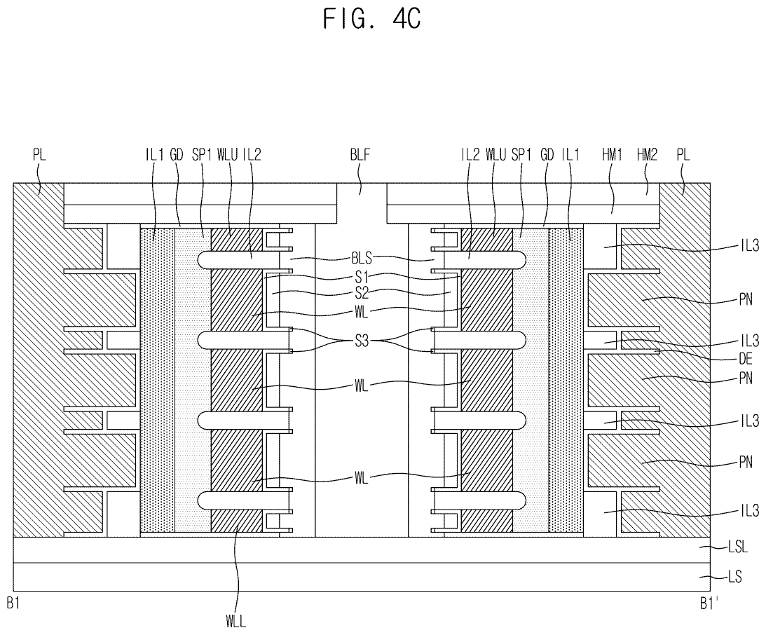

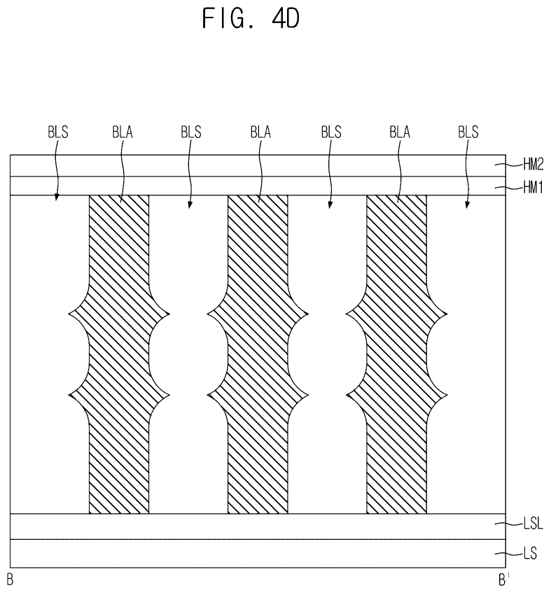

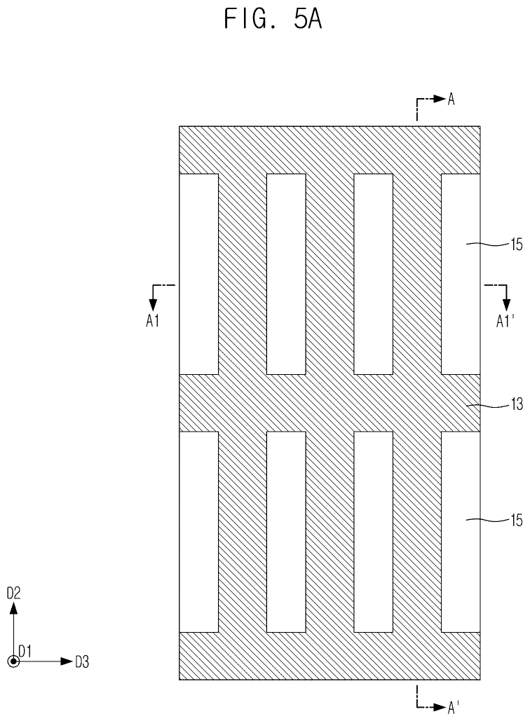

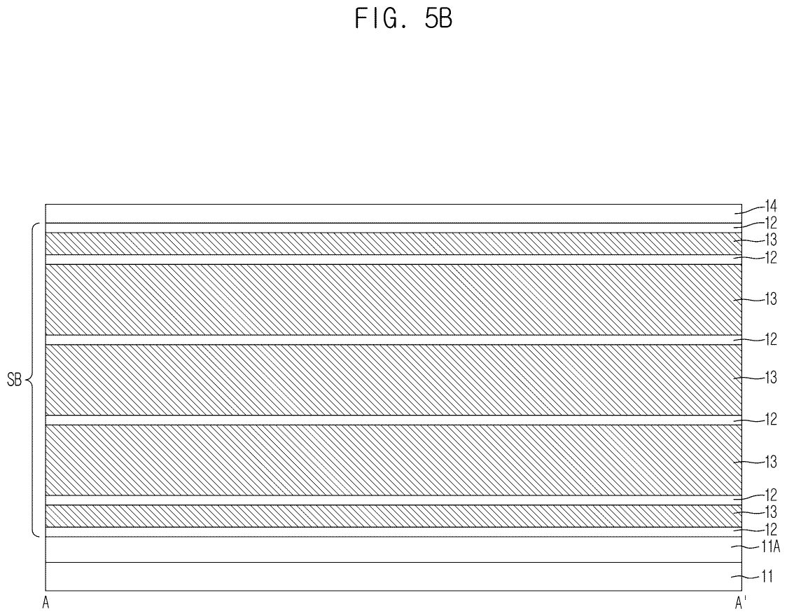

FIG. 3A is a schematic perspective view illustrating a semiconductor device 100 in accordance with an embodiment of the present disclosure. FIG. 3B is a schematic plan view illustrating the semiconductor device 100 in accordance with an embodiment of the present disclosure. FIG. 4A is a schematic cross-sectional view of the semiconductor device 100 taken along line A-A′ illustrated in FIG. 3B. FIG. 4B is a schematic cross-sectional view of the semiconductor device 100 taken along line A1-A1′ illustrated in FIG. 3B. FIG. 4C is a schematic cross-sectional view of the semiconductor device 100 taken along line B-B′ illustrated in FIG. 3B. FIG. 4D is a schematic cross-sectional view of the semiconductor device 100 taken along line B1-B1′ illustrated in FIG. 3B. Detailed descriptions of overlapping components below are provided above with reference to FIGS. 1A to 2F.

Referring to FIGS. 3A to 4D, the semiconductor device 100 may include a memory cell array MCA. The memory cell array MCA may include a three-dimensional array of memory cells MC. Each of the memory cells MC may include a first conductive line BL, a switching element TR, and a data storage element CAP, and the switching element TR may include a second conductive line WL, a nano sheet dielectric layer GD, and a nano sheet HL, as shown, for example, in FIGS. 1A and 1B.

The memory cell array MCA may include a first sub-cell array MCA1 and a second sub-cell array MCA2. The first sub-cell array MCA1 and the second sub-cell array MCA2 may each include a three-dimensional array of the memory cells MC. The memory cells MC in the first sub-cell array MCA1 may share a first vertical conductive line BLA, and the memory cells MC in the second sub-cell array MCA2 may share a second vertical conductive line BLB. From the perspective of a top view, the first and second vertical conductive lines BLA and BLB may each have a rectangular shape. A bottom portion of the first vertical conductive line BLA and a bottom portion of the second vertical conductive line BLB may be electrically isolated from each other.

The first sub-cell array MCA1 may include a horizontal arrangement and a vertical arrangement of the memory cells MC. Each of the memory cells MC of the first sub-cell array MCA1 may include the first vertical conductive line BLA, a switching element TR, and a data storage element CAP. The switching element TR may include a second conductive line WL and a nano sheet HL. The switching elements TR of the memory cells MC may be nano sheet transistors. The first sub-cell array MCA1 may include a horizontal arrangement and a vertical arrangement of the nano sheet transistors. The first sub-cell array MCA1 may include a horizontal arrangement of the first vertical conductive lines BLA. The first sub-cell array MCA1 may include a horizontal arrangement and a vertical arrangement of the second conductive lines WL. The first sub-cell array MCA1 may include a horizontal arrangement and a vertical arrangement of the data storage elements CAP.

The second sub-cell array MCA2 may be a mirror image of the first sub-cell array MCA1. For example, the second sub-cell array MCA2 may include a horizontal arrangement and a vertical arrangement of the memory cells MC. Each of the memory cells MC of the second sub-cell array MCA2 may include the second vertical conductive line BLB, a switching element TR, and a data storage element CAP. The switching element TR may include a second conductive line WL and a nano sheet HL. The switching elements TR of the memory cells MC may be nano sheet transistors. The second sub-cell array MCA2 may include a horizontal arrangement and a vertical arrangement of the nano sheet transistors. The second sub-cell array MCA2 may include a horizontal arrangement of the second vertical conductive lines BLB. The second sub-cell array MCA2 may include a horizontal arrangement and a vertical arrangement of the second conductive lines WL. The second sub-cell array MCA2 may include a horizontal arrangement and a vertical arrangement of the data storage elements CAP.

The first conductive line BL may vertically extend in a first direction D1, the nano sheet HL may extend in a second direction D2, and the second conductive line WL may horizontally extend in a third direction D3.

A first inter-cell dielectric layer IL1 may be disposed between the data storage elements CAP disposed adjacent to each other in the third direction D3. A second inter-cell dielectric layer IL2 may be disposed between the second conductive lines WL vertically stacked in the first direction D1. A third inter-cell dielectric layer IL3 may be disposed between first electrodes SN of the data storage elements CAP vertically stacked in the first direction D1. (See, e.g., FIG. 4A). The first to third inter-cell dielectric layers IL1, IL2 and IL3 may each include silicon oxide, silicon carbon oxide (SiCO), silicon nitride, or a combination thereof. The first inter-cell dielectric layer IL1 may be referred to as a “device isolation layer”.

Each of the memory cells MC may further include a first contact node BLC and a second contact node SNC. The first contact node BLC may be disposed between the first and second vertical conductive lines (BLA and BLB) and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and a first doped region SR may include an impurity diffused from the first contact node BLC.

The second contact node SNC may be disposed between the nano sheet HL and the first electrode SN of the data storage element CAP. The second contact node SNC may include a metal-based material or a semiconductive material. For example, the second contact node SNC may include titanium, titanium nitride, tungsten, or a combination thereof. In addition, the second contact node SNC may include doped polysilicon, and a second doped region DR may include an impurity diffused from the second contact node SNC. A height (or thickness) of the first contact node BLC in the first direction D1 may be less than a height (or thickness) of the second contact node SNC in the first direction D1. A height of the first contact node BLC in the first direction D1 may be greater than a height of a channel CH in the first direction D1. Each of the first and second contact nodes BLC and SNC may include phosphorus-doped polysilicon or arsenic-doped polysilicon.

Each of the memory cells MC may further include an ohmic contact layer BLO between the first contact node BLC and the first conductive line BL. The ohmic contact layer BLO may include metal silicide, such as titanium silicide or molybdenum silicide.

Each of the memory cells MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The first and second spacers SP1 and SP2 may each include a dielectric material. The first and second spacers SP1 and SP2 may each include silicon oxide, silicon nitride, or a combination thereof.

The second spacer SP2 may include a first sub-spacer S1, a third sub-spacer S3, and a second sub-spacer S2 between or coupled to (e.g., in contact with) the first sub-spacer S1 and the third sub-spacer S3. (e.g., see FIGS. 2A and 4A). The second spacer SP2 may include a combination of one first sub-spacer S1 and a pair of third sub-spacers S3.

The first sub-spacer S1 may have an integral structure, which surrounds the nano sheet HL on the nano sheet dielectric layer GD. The first sub-spacer S1 may include a plurality of recessed portions, and the second sub-spacer S2 and a fourth sub-spacer S2′ may be filled in the recessed portions. The second sub-spacer S2 may have a protruding structure, which vertically faces the nano sheet HL. The fourth sub-spacer S2′ may have a recessed structure, which is disposed in a horizontal space between the nano sheets HL.

The third sub-spacer S3 may be disposed on upper and lower portions of the nano sheet HL on the nano sheet dielectric layer GD.

The second spacer SP2 may extend in the third direction D3 while surrounding portions of the nano sheets HL, i.e., the first doped regions SR.

As described above, the first sub-spacer S1 may surround the third portions of the nano-sheets HL while contacting the second conductive line WL, and the pair of third sub-spacers S3 (see also FIG. 2F) may contact the first and second vertical conductive lines BLA and BLB and the first sub-spacer S1. The second sub-spacer S2 may be disposed between or coupled to (e.g., in contact with) the first sub-spacer S1 and the third sub-spacer S3 and may be disposed between the nano sheets HL in the vertical arrangement. The fourth sub-spacer S2′ may be disposed between the first sub-spacer S1 and the third sub-spacer S3 and may be disposed between the nano sheets HL in the horizontal arrangement.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BLA and BLB spaced apart in the third direction D3. The memory cell array MCA may include dummy second conductive lines WLU and WLL disposed at a level higher than an uppermost second conductive line WL and at a level lower than a lowermost second conductive line WL, respectively. (See FIG. 4B). The dummy second conductive lines WLU and WLL may each have a linear shape extending horizontally.

The memory cell array MCA may include a stack of a plurality of hard mask layers HM1 and HM2 disposed at a level higher than the uppermost second conductive line WL.

A lower structure LS and a stopper layer LSL may be disposed below the memory cell array MCA. The stopper layer LSL may prevent electrical contact between the first and second vertical conductive lines BLA and BLB and the lower structure LS. The stopper layer LSL may prevent electrical contact between the data storage element CAP and the lower structure LS. The stopper layer LSL may include a dielectric material. The lower structure LS may be a material suitable for semiconductor processing. The lower structure LS may include one or more of a conductive material, a dielectric material and a semiconductive material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The lower structure LS may also include another semiconductive material such as germanium. The lower structure LS may also include a III-V group semiconductor substrate, for example, a compound semiconductor substrate such as GaAs.

An inter-array dielectric layer BLF may be disposed between the first vertical conductive line BLA and the second vertical conductive line BLB. (See, e.g., FIG. 4A). The inter-array dielectric layer BLF may include a dielectric material. For example, the inter-array dielectric layer BLF may include silicon oxide with an air gap embedded therein.

The first and second vertical conductive lines BLA and BLB may be formed to be self-aligned with supporters BLS. The first vertical conductive lines BLA disposed adjacent to each other in the third direction D3 may be isolated from each other by the supporters BLS. The second vertical conductive lines BLB disposed adjacent to each other in the third direction D3 may be isolated from each other by the supporters BLS. The first vertical conductive lines BLA and the second vertical conductive lines BLB disposed adjacent to each other in the second direction D2 may be isolated from each other by the inter-array dielectric layer BLF.

The nano sheets HL of the switching elements TR horizontally disposed in the third direction D3 may share one second conductive line (e.g., gate electrode) WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

Referring back to FIG. 4B, the memory cell array MCA may include a vertical arrangement of the second conductive lines WL and a vertical arrangement of the second inter-cell dielectric layers IL2. Each of the second inter-cell dielectric layers IL2 may be disposed between the second conductive lines WL. A thickness of the second inter-cell dielectric layers IL2 may determine the spacing between the second conductive lines WL. The memory cell array MCA may include the dummy second conductive lines WLU and WLL disposed at a level higher than the uppermost second conductive line WL and at a level lower than the lowermost second conductive line WL, respectively. The dummy second conductive lines WLU and WLL may each have a linear shape extending horizontally.

The nano sheet dielectric layers GD may surround the nano sheets HL, and the second conductive lines WL may surround the nano sheets HL on the nano sheet dielectric layers GD.

The semiconductor device 100 may further include a plurality of supporters BLS (e.g., see FIG. 3B), and each of the supporters BLS may be disposed between an adjacent pair of the first vertical conductive lines BLAs or an adjacent pair of the second vertical conductive lines BLB in the third direction D3. Upper portions of the supporters BLS may extend to cover at least a portion of the second spacer SP2. The first and second vertical conductive lines BLA and BLB may be supported by the supporters BLS. The supporters BLS may vertically extend in the first direction D1. The supporters BLS may each include a dielectric material. The first and second vertical conductive lines BLA and BLB may be self-aligned with the supporters BLS and the second spacer SP2, and the supporters BLS may be vertically oriented in an extending direction of the first and second vertical conductive lines BLA and BLB. The supporters BLS may each include a low-k material, silicon carbon oxide, silicon nitride, an air gap, or a combination thereof.

According to FIGS. 1A to 4D, the semiconductor device 100 may include a horizontal arrangement of the switching elements TR each including the nano sheet HL and the second conductive line WL surrounding the nano sheet HL. The semiconductor device 100 may further include the first vertical conductive lines BLA, the data storage elements CAP and the supporters BLS. Each of the first vertical conductive lines BLA may be coupled to a corresponding one of first edges of the nano sheets HL in the horizontal arrangement. Each of the data storage elements CAP may be coupled to a corresponding one of second edges of the nano sheets HL in the horizontal arrangement. The supporters BLS may be disposed between the first vertical conductive lines BLA. The semiconductor device 100 may further include the plurality of first spacers SP1 disposed between the data storage elements CAP and the second conductive line WL, and surrounding the nano sheets HL. The semiconductor device 100 may further include the plurality of second spacers SP2 each having a multi-layer structure. The second spacers SP2 may be disposed between the first vertical conductive lines BLA and the second conductive line WL and may surround the nano sheets HL. The first vertical conductive lines BLA may be self-aligned with the supporters BLS and the plurality of second spacers SP2, and the supporters BLS may be vertically oriented in the extending direction of the first vertical conductive lines BLA.

According to FIGS. 1A to 4D, the semiconductor device 100 may include a horizontal arrangement of the switching elements TR each including the nano sheet HL and the second conductive line WL surrounding the nano sheet HL. The semiconductor device 100 may further include the second vertical conductive lines BLB, the data storage elements CAP and the supporters BLS. Each of the second vertical conductive lines BLB may be coupled to a corresponding one of first edges of the nano sheets HL in the horizontal arrangement. Each of the data storage elements CAP may be coupled to a corresponding one of second edges of the nano sheets HL in the horizontal arrangement. The supporters BLS may be disposed between the second vertical conductive lines BLB. The semiconductor device 100 may further include the plurality of first spacers SP1 disposed between the data storage elements CAP and the second conductive line WL, and surrounding the nano sheets HL. The semiconductor device 100 may further include the plurality of second spacers SP2 each having a multi-layer structure. The second spacers SP2 may be disposed between the second vertical conductive lines BLB and the second conductive line WL and may surround the nano sheets HL. The second vertical conductive lines BLB may be self-aligned with the supporters BLS and the plurality of second spacers SP2, and the supporters BLS may be vertically oriented in the extending direction of the second vertical conductive lines BLB.

According to FIGS. 1A to 4D, the semiconductor device 100 may include the first sub-cell array MCA1 including the horizontal arrangement of the first vertical conductive lines BLA, the second sub-cell array MCA2 including the horizontal arrangement of the second vertical conductive lines BLB, the inter-array dielectric layer BLF between the first sub-cell array MCA1 and the second sub-cell array MCA2, and the supporters disposed between the horizontal arrangements of the first vertical conductive lines BLA and between the horizontal arrangements of the second vertical conductive lines BLB. Each of the first and second sub-cell arrays MCA1 and MCA2 may include a three-dimensional array of the memory cells MC. Each of the memory cells MC may include a horizontal arrangement of the switching elements TR each including the nano sheet HL and the second conductive line WL surrounding the nano sheet HL. The nano sheet HL may include a narrow sheet NS and a wide sheet WS. Each of the memory cells MC may further include the first contact node BLC, the ohmic contact layer BLO, the second contact node SNC, and the data storage element CAP.

FIGS. 5A to 31B illustrate operations included in a method for fabricating the semiconductor device in accordance with an embodiment of the present disclosure. The semiconductor device may correspond to any of the embodiments of the semiconductor device previously discussed.

FIG. 5A is a plan view illustrating a structure at a second mold layer level to describe an operation for forming a mold stack SB. FIG. 5B is a cross-sectional view of the structure taken along line A-A′ illustrated in FIG. 5A. FIG. 5C is a cross-sectional view of the structure taken along line A1-A1′ illustrated in FIG. 5A.

Referring to FIGS. 5A to 5C, a stopper layer 11A may be formed on a substrate 11, and the mold stack SB may be formed over the stopper layer 11A.

The substrate 11 may be a material suitable for semiconductor processing. The substrate 11 may include one or more of a conductive material, a dielectric material and a semiconductive material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The substrate 11 may also include another semiconductive material such as germanium. The substrate 11 may also include a Group III-V semiconductor substrate, for example, a compound semiconductor substrate such as GaAs.

The stopper layer 11A may include a dielectric material. The stopper layer 11A may include silicon oxide, silicon carbon oxide, or a combination thereof. The mold stack SB may include an alternating stack of first mold layers 12 and second mold layers 13.

The first mold layers 12 may be alternately stacked with the second mold layers 13. The first mold layers 12 and the second mold layers 13 may be epitaxially grown multiple times to form the mold stack SB. The first mold layer 12 may be disposed at the top of the mold stack SB. The second mold layers 13 may be processed in subsequent operations to form the nano sheets HL of the transistors TR of the semiconductor device.

The first mold layers 12 and the second mold layers 13 may be different semiconductive materials. The first mold layers 12 may include silicon germanium or monocrystalline silicon germanium. The second mold layers 13 may include monocrystalline silicon. The first mold layers 12 and the second mold layers 13 may be formed by an epitaxial growth process. A lowermost first mold layer 12 may serve as a seed layer during the epitaxial growth process. Each of the first mold layers 12 may be thinner than each of the second mold layers 13. The thickness of the mold layers 12 may determine the spacing between the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of each of the first mold layers 12 may be approximately 5 to 20 nm, and the thickness of each of the second mold layers 13 may be approximately 50 to 80 nm. The number of first mold layers 12 and the number of the second mold layers 13 in the mold stack SB may be variously modified. In some embodiments, a triple stack including the first mold layer 12, the second mold layer 13, and the first mold layer 12 may be defined at lowermost and uppermost portions of the mold stack SB. The second mold layer 13 of the triple stack may have a thickness less than the second mold layer 13 of the mold stack SB.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

In subsequent operations, some portions of the mold stack SB may be etched using the first hard mask layer 14 as a barrier, and a plurality of sacrificial isolation openings 15 may be formed. The sacrificial isolation openings 15 may be initial openings for cell isolation. From the perspective of a top view, cross-sections of the sacrificial isolation openings 15 may each have a predetermined shape, e.g., a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. An etch process for forming the sacrificial isolation openings 15 may stop at the stopper layer 11A.

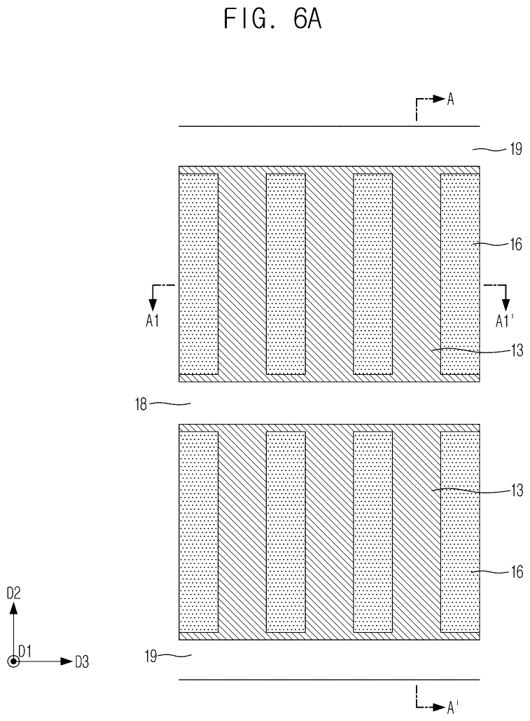

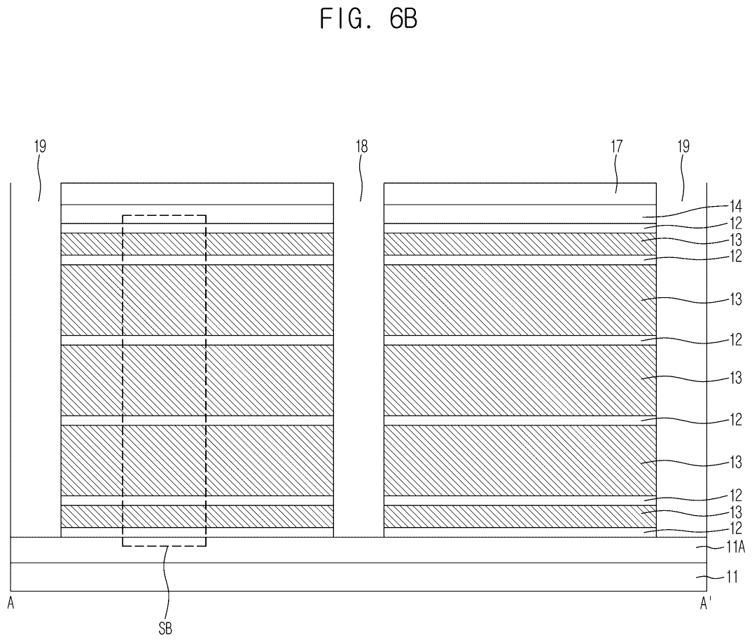

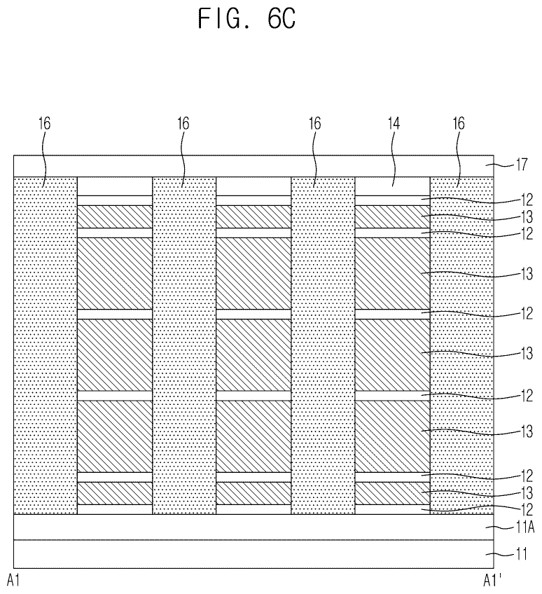

FIG. 6A is a plan view illustrating the structure at the second mold layer level to describe an operation for forming sacrificial linear openings 18 and 19. FIG. 6B is a cross-sectional view of the structure taken along line A-A′ illustrated in FIG. 6A. FIG. 6C is a cross-sectional view of the structure taken along line A1-A1′ illustrated in FIG. 6A

Referring to FIGS. 6A to 6C, sacrificial isolation layers 16 may be formed to fill the sacrificial isolation openings 15. The sacrificial isolation layers 16 may include the same material. The sacrificial isolation layers 16 may be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the mold stack SB to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. Each of the sacrificial isolation layers 16 may include a stack of a first sacrificial sub-spacer layer and a first sacrificial gap-fill layer. The first sacrificial sub-spacer layer may be silicon nitride, and the first sacrificial gap-fill layer may be silicon oxide. The sacrificial isolation layers 16 may penetrate the mold stack SB in the first direction D1, e.g., see FIG. 6C.

Subsequently, a second hard mask layer 17 may be formed on the mold stack SB and the sacrificial isolation layers 16. The second hard mask layer 17 may include silicon nitride. The second hard mask layer 17 may be formed by etching a second hard mask material using a mask layer such as photoresist. The second hard mask layer 17 may have a plurality of line-shaped openings defined therein.

Some portions of the mold stack SB may be etched using the second hard mask layer 17 as an etch barrier. Accordingly, a plurality of sacrificial linear openings 18 and 19 may be formed between the sacrificial isolation layers 16. The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The first sacrificial linear opening 18 may be aligned for subsequently dividing the semiconductor device into adjacent memory cell arrays, e.g., see FIG. 4A.

The sacrificial isolation layers 16 may be disposed between the first sacrificial linear opening 18 and the second sacrificial linear opening 19 in the second direction D2. From the perspective of a top view (e.g., see FIG. 6A), cross sections of the first and second sacrificial linear openings 18 and 19 may each have a rectangular shape. In some embodiments, the cross sections of the first and second sacrificial linear openings 18 and 19 may each have a circular shape or an oval shape. The first and second sacrificial linear openings 18 and 19 may each have a width in the second direction D2 less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

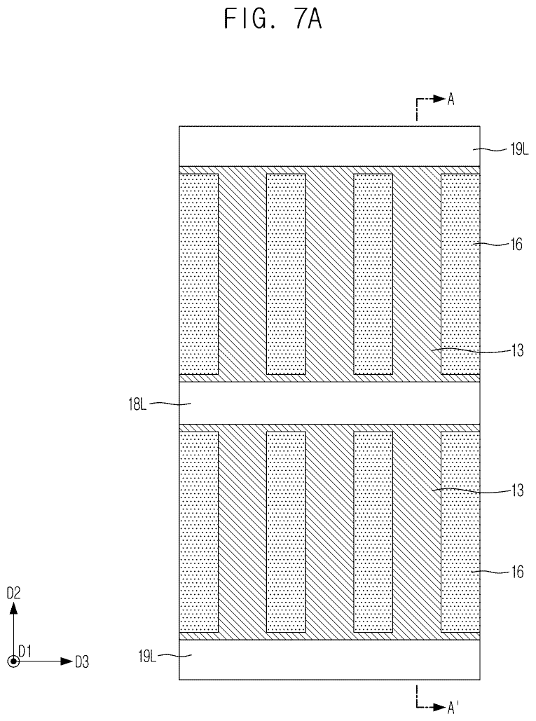

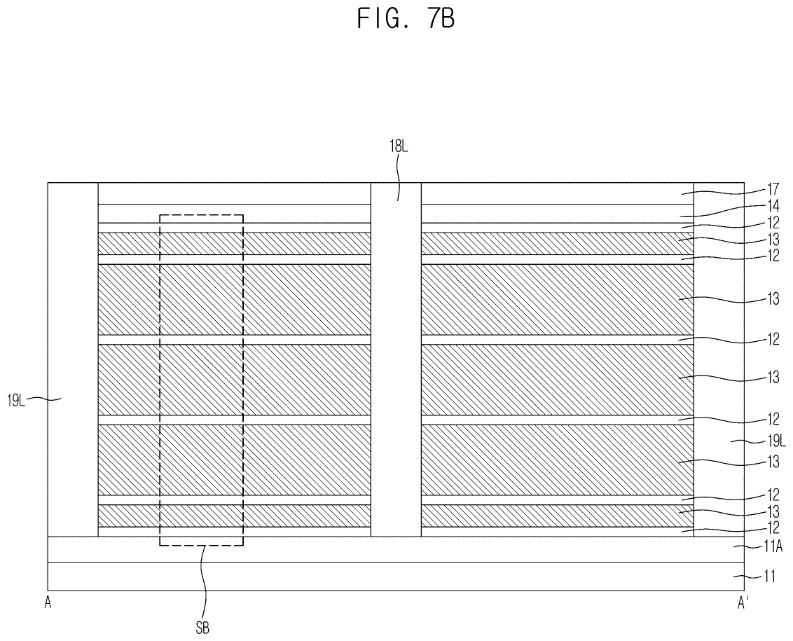

FIG. 7A is a plan view illustrating the structure at the second mold layer level to describe an operation for forming linear sacrificial layers 18L and 19L, and FIG. 7B is a cross-sectional view of the structure taken along line A-A′ illustrated in FIG. 7A.

Referring to FIGS. 7A and 7B, linear sacrificial layers 18L and 19L may be formed to fill the first and second sacrificial linear openings 18 and 19. The linear sacrificial layers may include a first linear sacrificial layer 18L and a second linear sacrificial layers 19L. From the perspective of a top view (e.g., FIG. 7A), the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

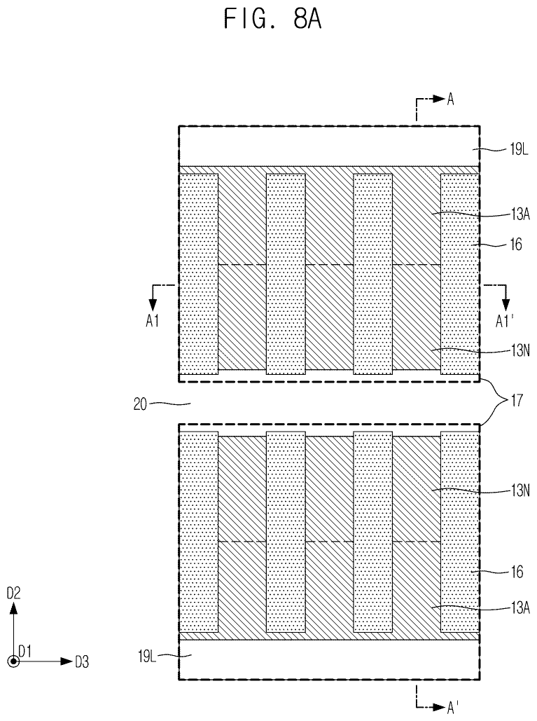

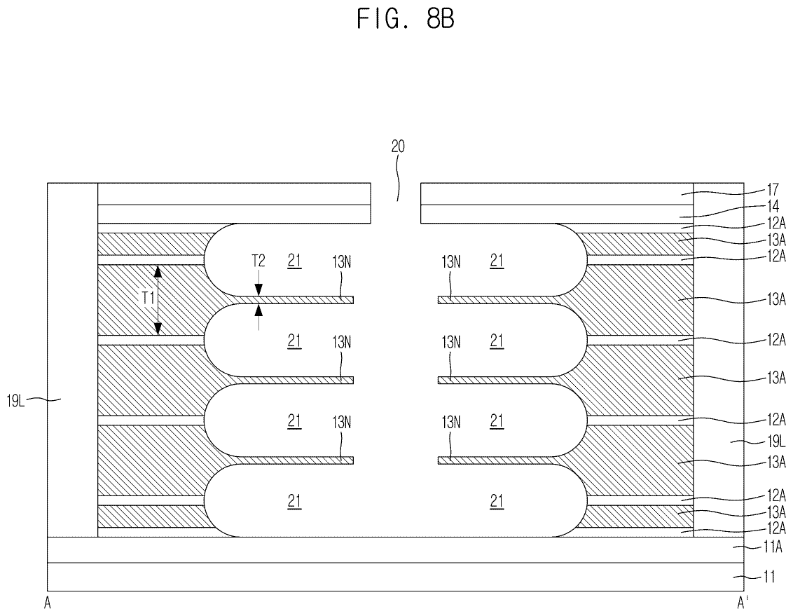

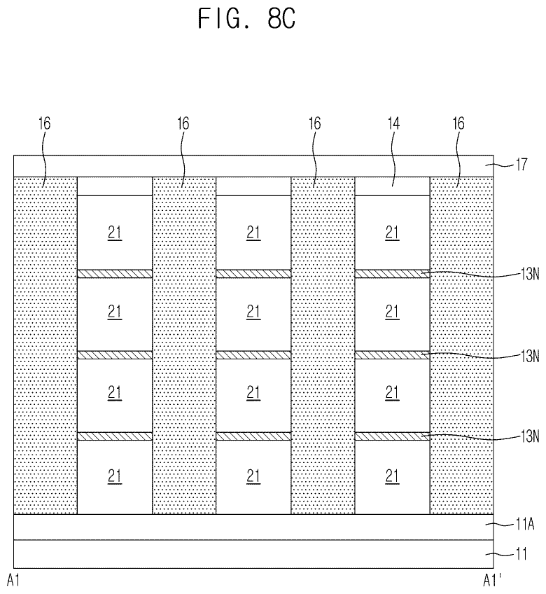

FIG. 8A is a plan view illustrating the structure at the second mold layer level to describe an operation for recessing the second mold layers 12. FIG. 8B is a cross-sectional view of the structure taken along line A-A′ illustrated in FIG. 8A. FIG. 8C is a cross-sectional view of the structure taken along line A1-A1′ illustrated in FIG. 8A.

Referring to FIGS. 8A to 8C, among the first linear sacrificial layer 18L and the second linear sacrificial layer 19L, the first linear sacrificial layer 18L may be selectively removed. A third hard mask layer 17T may be used as an etch barrier to remove the first linear sacrificial layer 18L. Accordingly, a first linear opening 20 may be formed. From the perspective of a top view, the first linear opening 20 may be disposed horizontally spaced apart from the second linear sacrificial layer 19L in the second direction D2.

An etch process for forming the first linear opening 20 may stop at the stopper layer 11A.

Subsequently, the first mold layers 12 and the second mold layers 13 may be selectively recessed through the first linear openings 20. The selective recessing of these layers may form narrow sheets 13N that will contribute, in subsequent operations, to the formation of the nano sheets HL, as shown, for example, in FIG. 4A.

A difference in etch selectivity between the first mold layers 12 and the second mold layers 13 may be used to selectively recess the first mold layers 12. The first mold layers 12 may be removed using a wet etch process or a dry etch process. For example, when the first mold layers 12 include silicon germanium layers, and the second mold layers 13 include monocrystalline silicon layers, the silicon germanium layers may be etched using an etchant or etch gas having a selectivity with respect to the monocrystalline silicon layers. Portions of the first mold layers 12, each having an original thickness, may remain as indicated by reference numeral “12A,” e.g., see FIG. 8B.

Subsequently, a portion (a first portion) of each of the second mold layers 13 may be recessed to form a narrow sheet 13N. The narrow sheet 13N may correspond to the location of the narrow sheet NS shown, for example, in FIG. 1B. A wet etch process or dry etch process may be used to recess the second mold layers 13. An original body portion 13A and the narrow sheet 13N may be formed by the partial recessing of each of the second mold layers 13. The original body portion 13A may maintain an original thickness T1, and the narrow sheet 13N may have a thickness T2 less than the original thickness T1. A horizontal length of the original body portion 13A in the second direction D2 may be equal to or different from a horizontal length of the narrow sheet 13N in the second direction D2 . . . . A combination of the original body portion 13A and the narrow sheet 13N may be referred to as a “preliminary active layer”. The narrow sheet 13N may be referred to as a “flat plate-shaped sheet” or a “protruding narrow sheet”.

A recess process for forming the narrow sheet 13N may be referred to as a “thinning process” or “trimming process” of the second mold layer 13. To form the narrow sheet 13N, an upper surface, lower surface and side surface of the second mold layer 13 may be recessed. The narrow sheet 13N may be referred to as a “thin-body active layer”. The narrow sheet 13N may include a monocrystalline silicon layer. The recess process for forming the narrow sheet 13N may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13N may be formed by the partial recess process for the second mold layers 13 as described above. Inter-nano sheet recesses 21 may be formed between adjacent ones of the narrow sheets 13N that are vertically disposed. The inter-nano sheet recesses 21 may provide space for, among other features, the formation of the second conductive lines WLL and spacers of the memory cells.

Upper and lower surfaces of the narrow sheets 13N may each include a flat surface. A boundary portion between the original body portion 13A and the narrow sheet 13N may be vertical or have a curvature. Each of the first mold layers 12A may be disposed between the original body portions 13A that are vertically stacked. A horizontal arrangement and a vertical arrangement of the narrow sheets 13N may be formed over the stopper layer 11A.

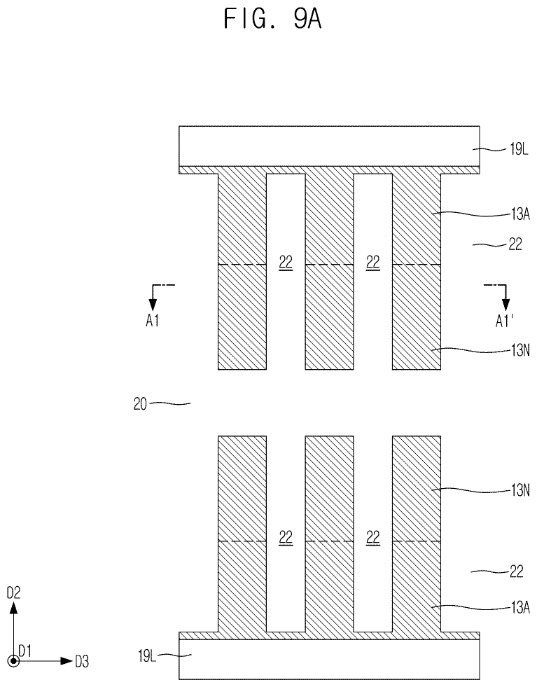

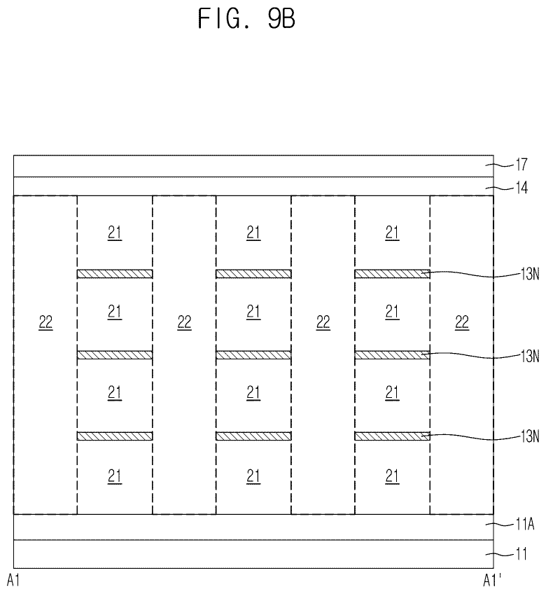

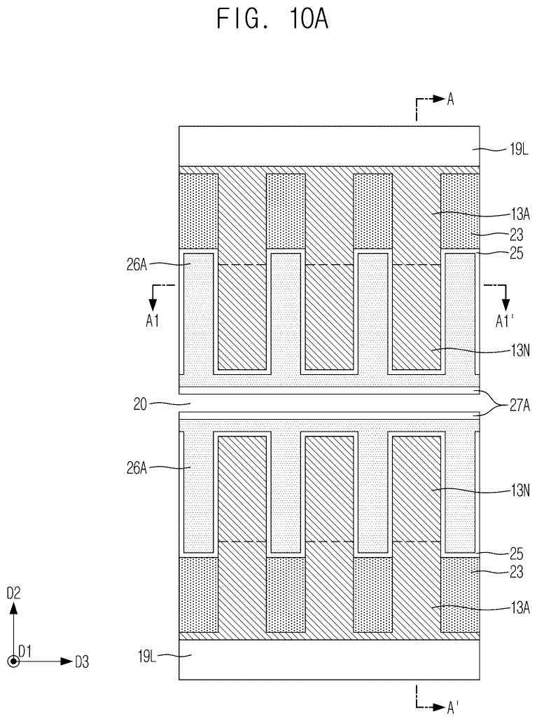

FIG. 9A is a plan view illustrating the structure at a narrow sheet level to describe an operation for forming sacrificial isolation layer-level openings 22. FIG. 9B is a cross-sectional view of the structure taken along line A1-A1′ illustrated in FIG. 9A.

Referring to FIGS. 9A and 9B, the sacrificial isolation layers 16 may be selectively stripped through the inter-nano sheet recesses 21. Accordingly, each of the sacrificial isolation layer-level openings 22 may be formed between the original body portions 13A in the third direction D3. Side surfaces of the first mold layers 12A, side surfaces of the original body portions 13A and side surfaces of the narrow sheets 13N may be exposed in the third direction D3 by the sacrificial isolation layer-level openings 22.

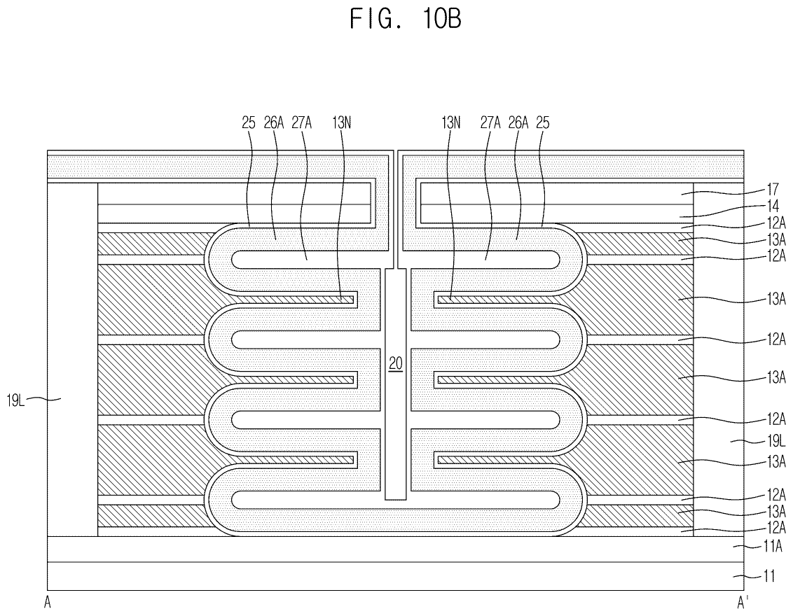

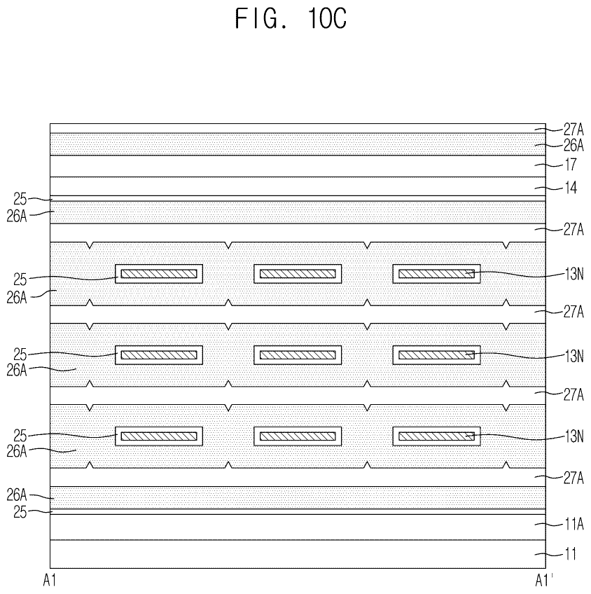

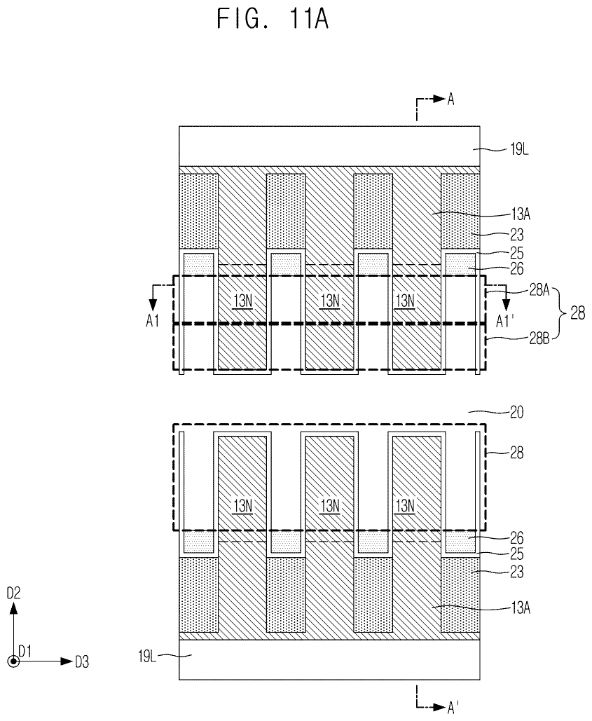

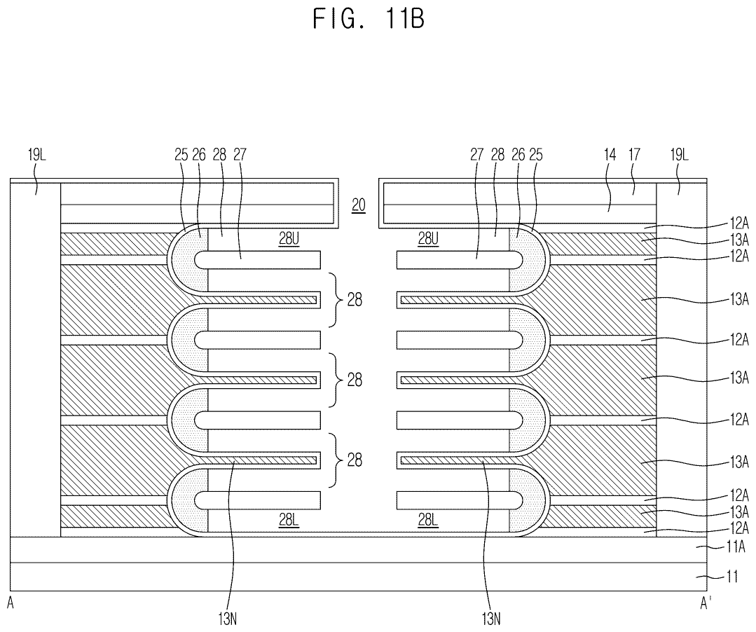

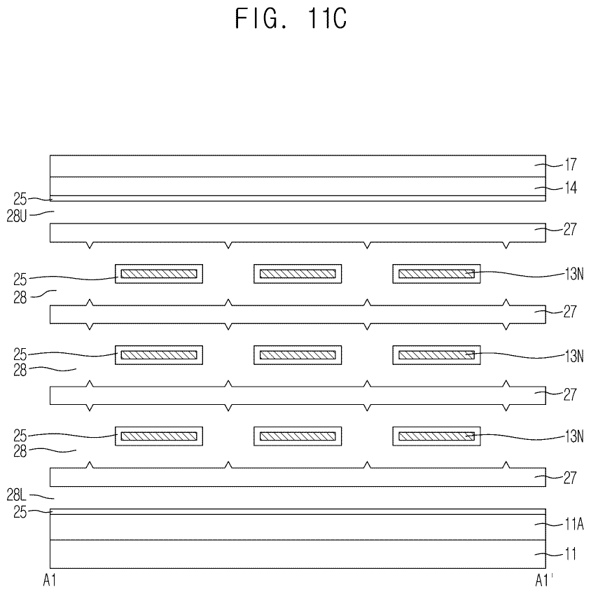

FIG. 10A is a plan view illustrating the structure at the narrow sheet level to describe an operation for forming first inter-cell dielectric layers 23, a first spacer layer 26A and a second inter-cell dielectric layer 27A. FIG. 10B is a cross-sectional view of the structure taken along line A-A′ illustrated in FIG. 10A. FIG. 10C is a cross-sectional view of the structure taken along line A1-A1′ illustrated in FIG. 10A.

Referring to FIGS. 10A to 10C, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13N. The other portions of the sacrificial isolation layer-level openings 22, i.e., non-gap-filled portions, may expose the side surfaces of the narrow sheets 13N.

Subsequently, a nano sheet dielectric layer 25 may be formed on the exposed portions of the narrow sheets 13N. The nano sheet dielectric layer 25 may be referred to as a “gate dielectric layer,” e.g., may be used to form the gate dielectric layer GD of the transistor of each memory cell, as shown, for example, in FIG. 1B.

The nano sheet dielectric layer 25 may be formed by oxidizing the surfaces of the narrow sheets 13N. In some embodiments, the nano sheet dielectric layer 25 may be formed by a deposition process and an oxidation process of silicon oxide. The nano sheet dielectric layer 25 may include silicon oxide, silicon nitride, metal oxide, metal oxide nitride, metal silicate, a high-k material, a ferroelectric material, an anti-ferroelectric material, or a combination thereof. The nano sheet dielectric layer 25 may include SiO₂, Si₃N₄, HfO₂, Al₂O₃, ZrO₂, AlON, HfON, HfSiO, HfSiON, or a combination thereof. The nano sheet dielectric layer 25 may be formed on all surfaces of the narrow sheets 13N.

The first spacer layer 26A may be formed on the nano sheet dielectric layer 25. The first spacer layer 26A may include silicon nitride. The first spacer layer 26A may surround and cover the narrow sheets 13N on the nano sheet dielectric layer 25. This is also shown by reference numeral 26 in FIG. 10B. The first spacer layer 26A may be thicker than the nano sheet dielectric layer 25 and may be aligned to form at least the spacer SP1 shown in FIG. 1B.

The second inter-cell dielectric layer 27A may be formed on the first spacer layer 26A. The second inter-cell dielectric layer 27A may include silicon oxide. The nano sheet dielectric layer 25 and the first spacer layer 26A (see also reference numeral 26 in FIG. 10B) may also be formed on the surface of the stopper layer 11A.

As described above, the first spacer layer 26A may be disposed between the narrow sheets 13N in the third direction D3.

FIG. 11A is a plan view illustrating the structure at the narrow sheet level to describe an operation for forming first spacers 26, e.g., first spacer SP1 in FIG. 1B. FIG. 11B is a cross-sectional view of the structure taken along line A-A′ illustrated in FIG. 11A. FIG. 11C is a cross-sectional view of the structure taken along line A1-A1′ illustrated in FIG. 11A.

Referring to FIGS. 11A to 11C, the second inter-cell dielectric layer 27A may be cut through the first linear opening 20. Subsequently, the first spacer layer 26A may be selectively recessed. The remaining first spacer layers may become the first spacers 26, and the second inter-cell dielectric layer may remain as indicated by reference numeral “27”.

As the first spacers 26 are formed to have a U-shape, and linear surrounding recesses 28 surrounding the narrow sheets 13N may be formed on the nano sheet dielectric layer 25. Each of the second inter-cell dielectric layers 27 may be disposed between the linear surrounding recesses 28 that are vertically disposed. An upper-level dummy horizontal recess 28U may be formed on an uppermost second inter-cell dielectric layer 27, and a lower-level dummy horizontal recess 28L may be formed below a lowermost second inter-cell dielectric layer 27. The upper-level and lower-level dummy horizontal recesses 28U and 28L may each have a non-surrounding shape, e.g., a flat shape.

The first spacers 26 may surround first portions of the narrow sheets 13N at the same horizontal level on the nano sheet dielectric layer 25.

Each of the linear surrounding recesses 28 may include a first surrounding recess 28A and a second surrounding recess 28B. The first surrounding recess 28A may be disposed adjacent to the first spacer 26, and the second surrounding recess 28B may be disposed adjacent to the first linear opening 20. The first surrounding recesses 28A may be spaces in which horizontal conductive lines (second conductive lines WL in FIG. 1B) are to be formed, and the second surrounding recesses 28B may be spaces in which a second spacer (e.g., second spacer SP2) is to be formed.

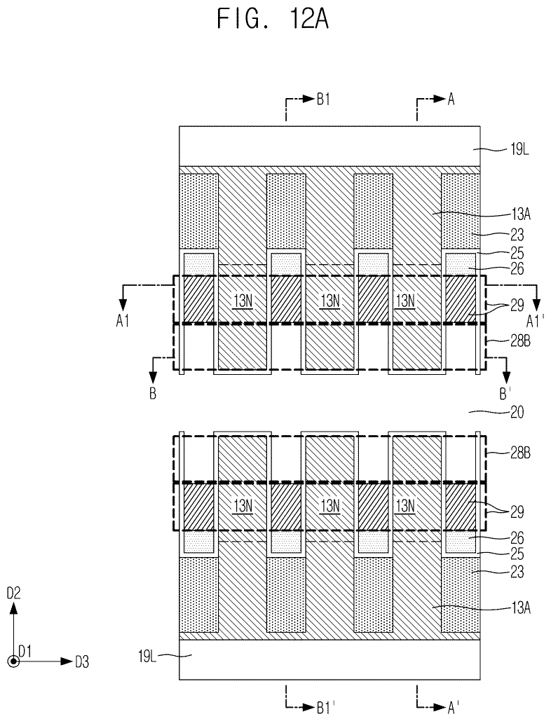

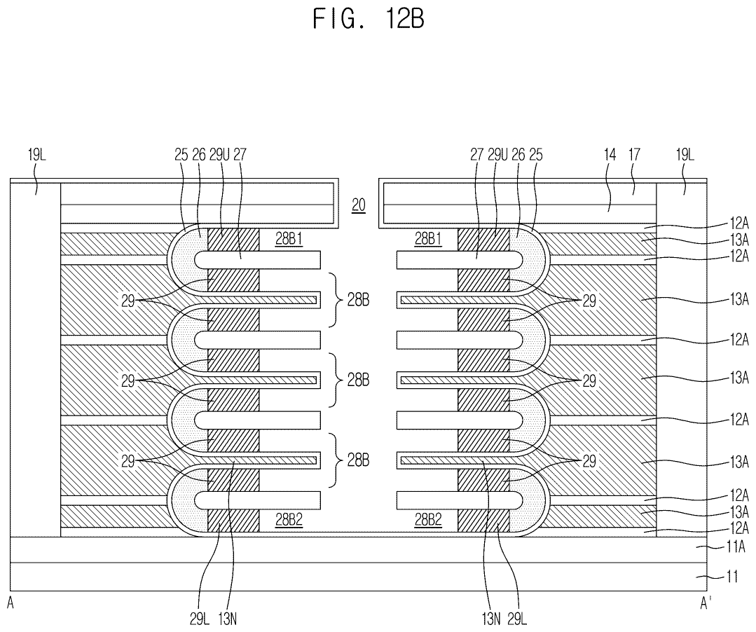

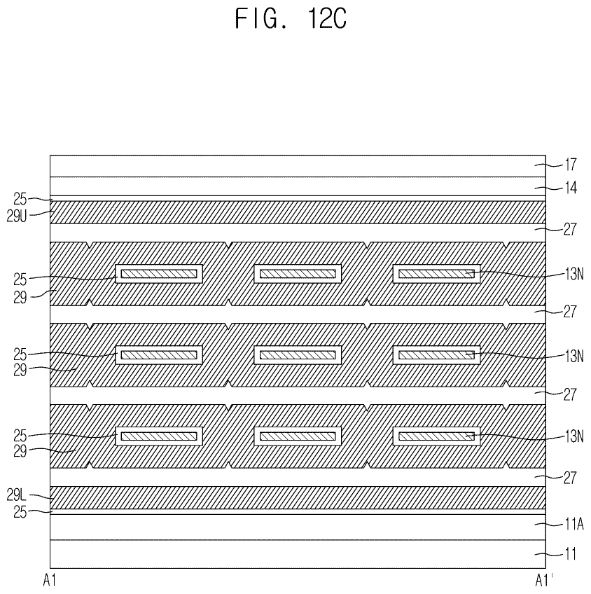

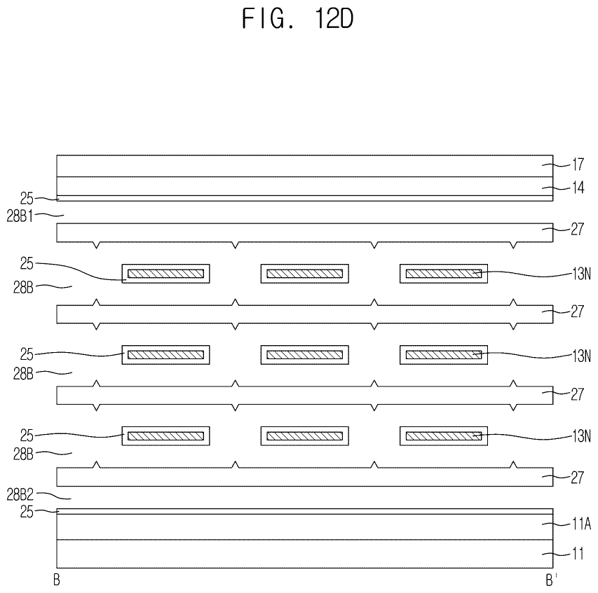

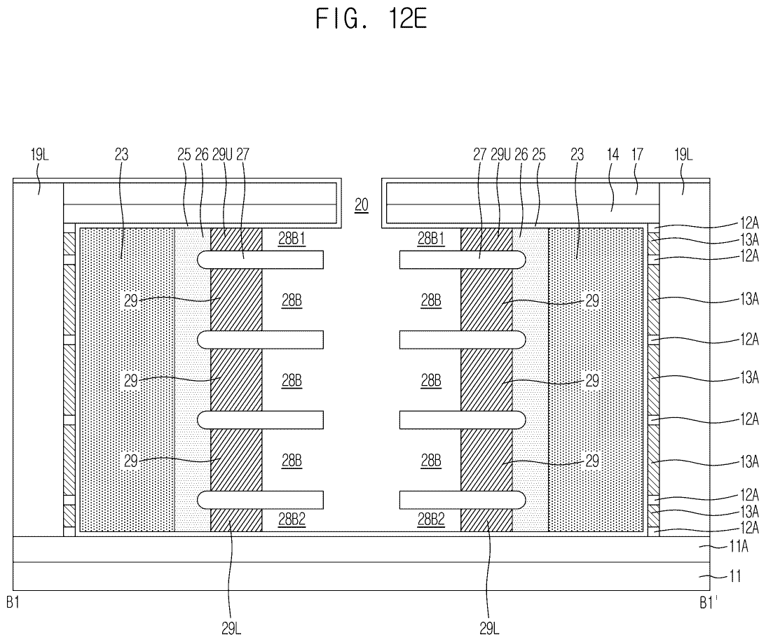

FIG. 12A is a plan view illustrating the structure at the narrow sheet level to describe an operation for forming horizontal conductive lines 29, e.g., second conductive lines WL. FIG. 12B is a cross-sectional view of the structure taken along line A-A′ illustrated in FIG. 12A. FIG. 12C is a cross-sectional view of the structure taken along line A1-A1′ illustrated in FIG. 12A. FIG. 12D is a cross-sectional view of the structure taken along line B-B′ illustrated in FIG. 12A. FIG. 12E is a cross-sectional view of the structure taken along line B1-B1′ illustrated in FIG. 12A.

Referring to FIGS. 12A to 12E, the horizontal conductive lines 29 filling the first surrounding recesses 28A of the linear surrounding recesses 28 may be formed. The horizontal conductive lines 29 may horizontally extend in the third direction D3.

Forming the horizontal conductive lines 29 may include depositing a conductive material filling the linear surrounding recesses 28 on the nano sheet dielectric layer 25 and performing a horizontal etch-back process on the conductive material. Each of the horizontal conductive lines 29 may simultaneously surround the narrow sheets 13N (at soon to-be-formed channel regions CH, see FIG. 1B) at the same level.

The horizontal conductive lines 29 may each include a metal-based material, a semiconductive material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or less, and the P-type work function material may have a high work function of approximately 4.5 eV or greater. Each of the second inter-cell dielectric layers 27 may be disposed between a plurality of horizontal conductive lines 29 in the first direction D1. The horizontal conductive lines 29 surrounding the narrow sheets 13N may be referred to as “gate-all-around (GAA) electrodes”. The narrow sheets 13N may be referred to as “nano sheet channels”, “nano wires” or “nano wire channels”.

A lower-level dummy horizontal electrode 29L may be formed on the stopper layer 11A. An upper-level dummy horizontal electrode 29U may be formed over an uppermost horizontal conductive line 29. The dummy horizontal electrodes 29L and 29U may each have a non-surrounding shape.

The horizontal conductive lines 29 may surround second portions of the narrow sheets 13N at the same horizontal level on the nano sheet dielectric layer 25.

After the horizontal conductive lines 29 are formed, the second surrounding recesses 28B may be opened between the narrow sheets 13N. The second surrounding recesses 28B may be spaces in which the second spacer (e.g., second spacer SP2 in FIG. 1B) is to be formed.

The second surrounding recesses 28B may surround the narrow sheets 13N at the same horizontal level on the nano sheet dielectric layer 25. Each of the second inter-cell dielectric layers 27 may be disposed between the second surrounding recesses 28B disposed vertically. Second surrounding recesses 28B1 having a non-surrounding shape may be disposed over the uppermost second inter-cell dielectric layer 27. Second surrounding recesses 28B2 having a non-surrounding shape may be disposed below the lowermost second inter-cell dielectric layer 27.

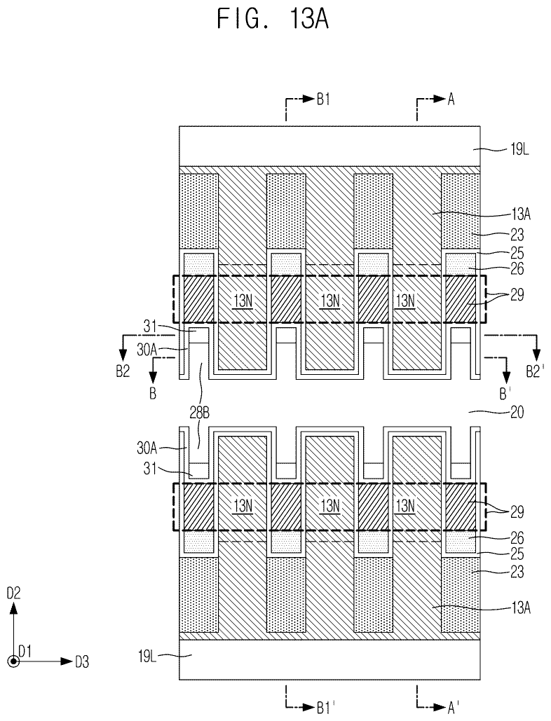

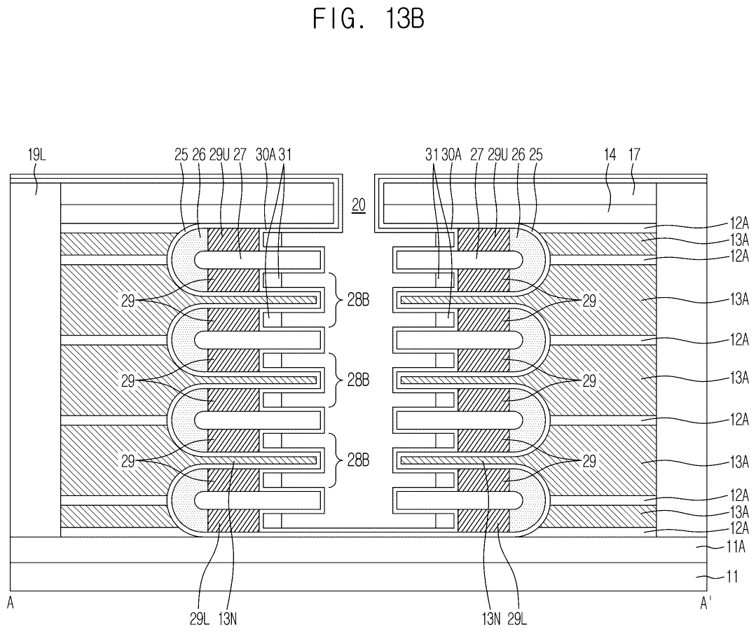

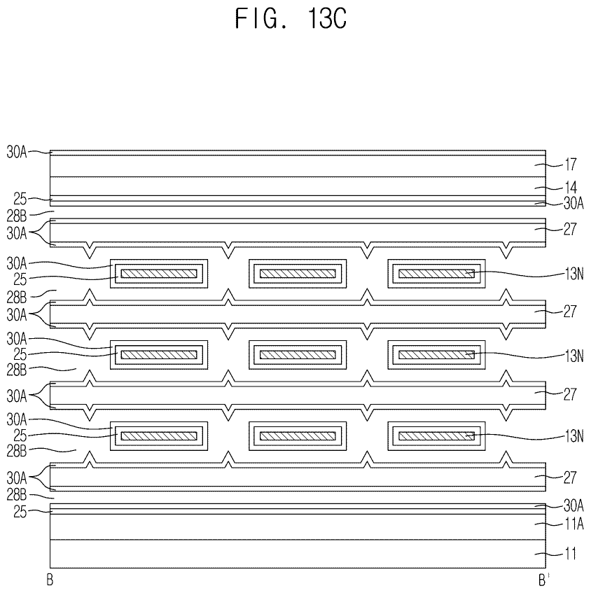

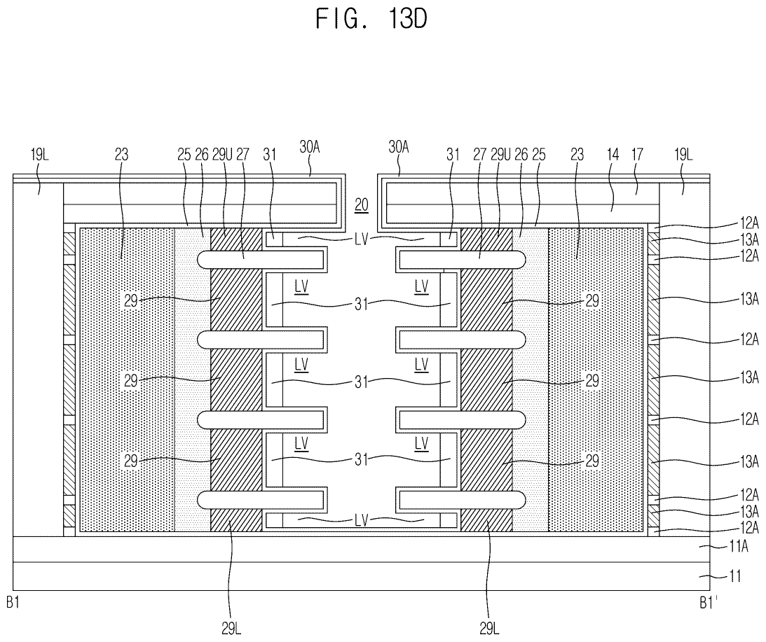

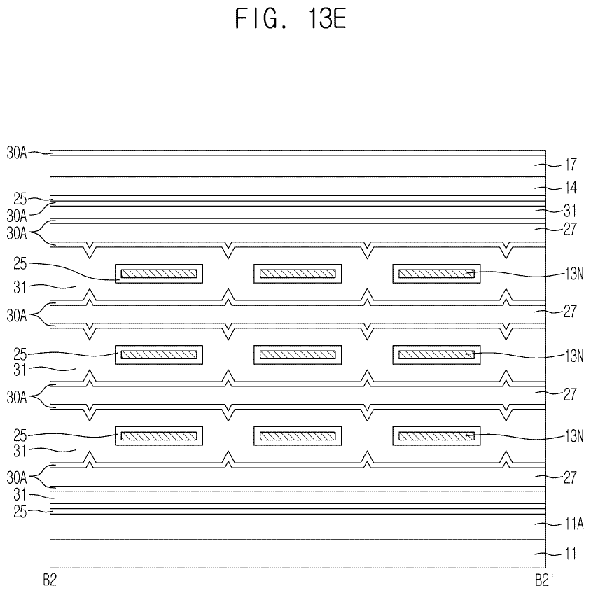

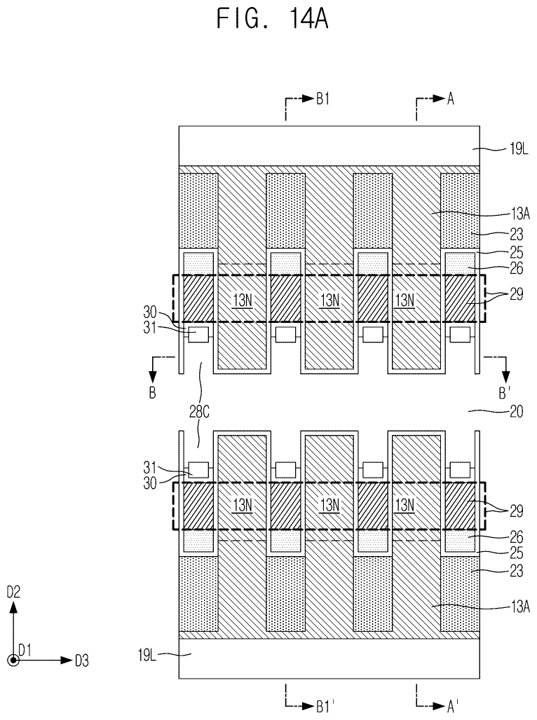

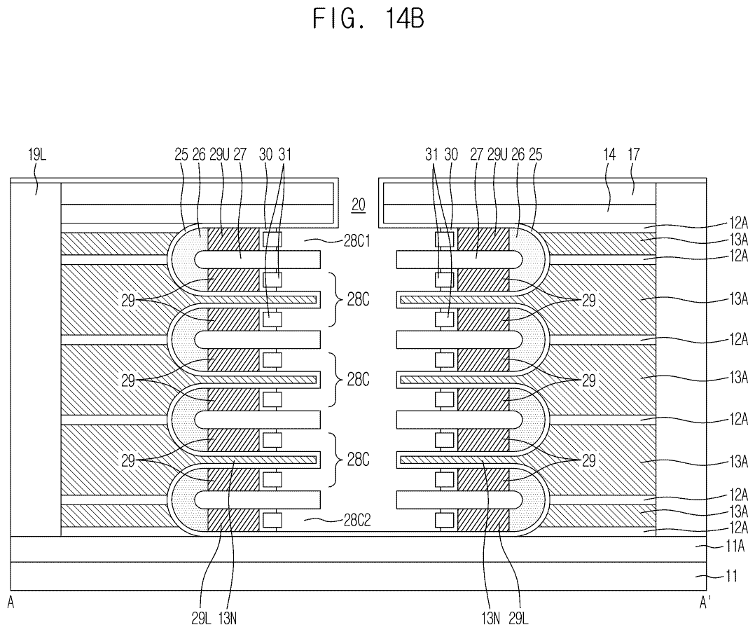

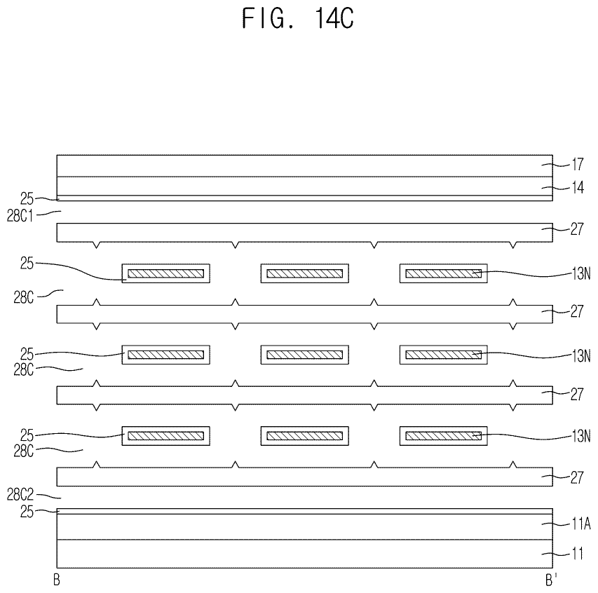

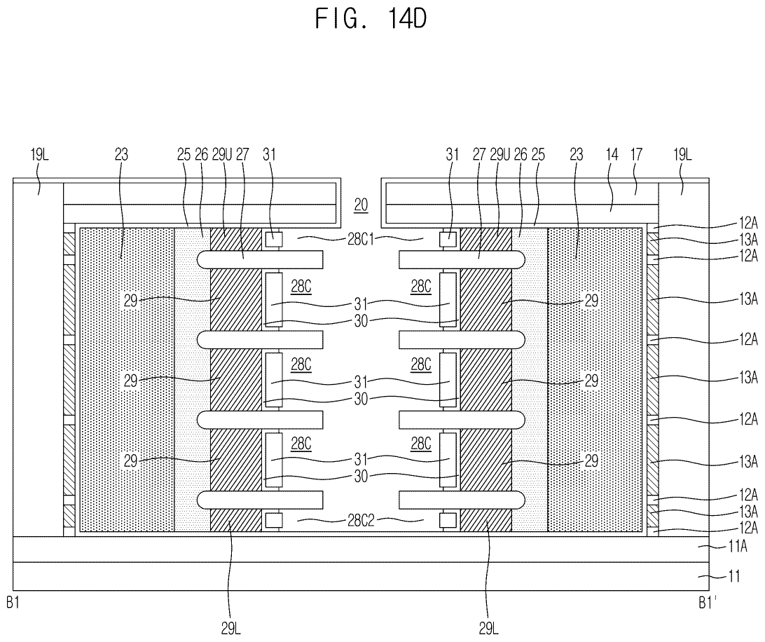

FIG. 13A is a plan view illustrating the structure at the narrow sheet level to describe an operation for forming a first sub-spacer layer 30A. FIG. 13B is a cross-sectional view of the structure taken along line A-A′ illustrated in FIG. 13A. FIG. 13C is a cross-sectional view of the structure taken along line B-B′ illustrated in FIG. 13A. FIG. 13D is a cross-sectional view of the structure taken along line B1-B1′ illustrated in FIG. 13A. FIG. 13E is a cross-sectional view of the structure taken along line B2-B2′ illustrated in FIG. 13A.

Referring to FIGS. 13A to 13E, a plurality of sub-spacer materials may be formed in the second surrounding recesses 28B. The sub-spacer materials may correspond to the sub-spacers of the second spacer SP2 shown, for example, in FIG. 1B.

The first sub-spacer layer 30A may be formed on one side of the horizontal conductive lines 29. The first sub-spacer layer 30A may include silicon oxide, silicon nitride, silicon carbon oxide, an embedded air gap, or a combination thereof. The first sub-spacer layer 30A may be conformally formed on one side of the horizontal conductive lines 29 and surround all surfaces of the narrow sheets 13N on the nano sheet dielectric layer 25. The first sub-spacer layer 30A may cover upper and lower surfaces of the second inter-cell dielectric layers 27.

Subsequently, a second sub-spacer 31 may be formed on the first sub-spacer layer 30A. The second sub-spacer 31 may partially fill non-gap-fill surrounding recesses LV on the first sub-spacer layer 30A. The first sub-spacer layer 30A and the second sub-spacer 31 may be different materials. In an embodiment, the first sub-spacer layer 30A may include silicon nitride, and the second sub-spacer 31 may include silicon oxide. Forming the second sub-spacer 31 may include depositing a second sub-spacer material and performing an etch-back process on the second sub-spacer material in the second direction D2.

The second sub-spacer 31 may surround surfaces of the narrow sheets 13N on the first sub-spacer layer 30A.

The first sub-spacer layer 30A and the second sub-spacer 31 may fill a space between the second inter-cell dielectric layers 27, i.e., the second surrounding recesses 28B.

After the first sub-spacer layer 30A and the second sub-spacer 31 are formed, the second surrounding recesses 28B may be reduced in size or volume.

FIG. 14A is a plan view illustrating the structure at the narrow sheet level to describe an operation for forming a first sub-spacer 30. FIG. 14B is a cross-sectional view of the structure taken along line A-A′ illustrated in FIG. 14A. FIG. 14C is a cross-sectional view of the structure taken along line B-B′ illustrated in FIG. 14A. FIG. 14D is a cross-sectional view of the structure taken along line B1-B1′ illustrated in FIG. 14A.

Referring to FIGS. 14A to 14D, the first sub-spacer layer 30A may be selectively recessed using the second sub-spacer 31 as a barrier, and thus the first sub-spacer 30 (e.g., sub-spacer S1 in FIG. 1B) may be formed. The first sub-spacer 30 may surround surfaces of the narrow sheets 13N on the nano sheet dielectric layer 25. An outer side of the second sub-spacer 31 may partially protrude by the first sub-spacer 30. The second sub-spacer 31 may fill an inner space of the first sub-spacer 30 and, for example, may correspond to the second sub-spacer S2 shown in FIG. 1B.

The first sub-spacer 30 and the second sub-spacer 31 may surround a third portion of each of the narrow sheets 13N (e.g., first doped region SR) at the same horizontal level on the nano sheet dielectric layer 25.

After the first sub-spacer 30 and the second sub-spacer 31 are formed, the second surrounding recesses 28B may be reduced in size or volume. For example, third surrounding recesses 28C may be defined.

The third surrounding recesses 28C may surround fourth portions of the narrow sheets 13N at the same horizontal level on the nano sheet dielectric layer 25. Each of the second inter-cell dielectric layers 27 may be disposed between the third surrounding recesses 28C disposed vertically. Third surrounding recesses 28C1 having a non-surrounding shape may be disposed over the uppermost second inter-cell dielectric layer 27. Third surrounding recesses 28C2 having a non-surrounding shape may be disposed below the lowermost second inter-cell dielectric layer 27. The first sub-spacer 30 may not be disposed between the third surrounding recesses 28C disposed vertically.

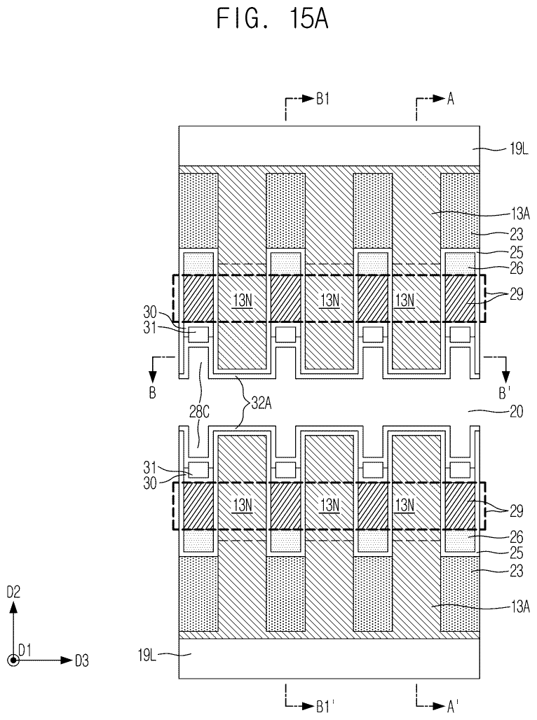

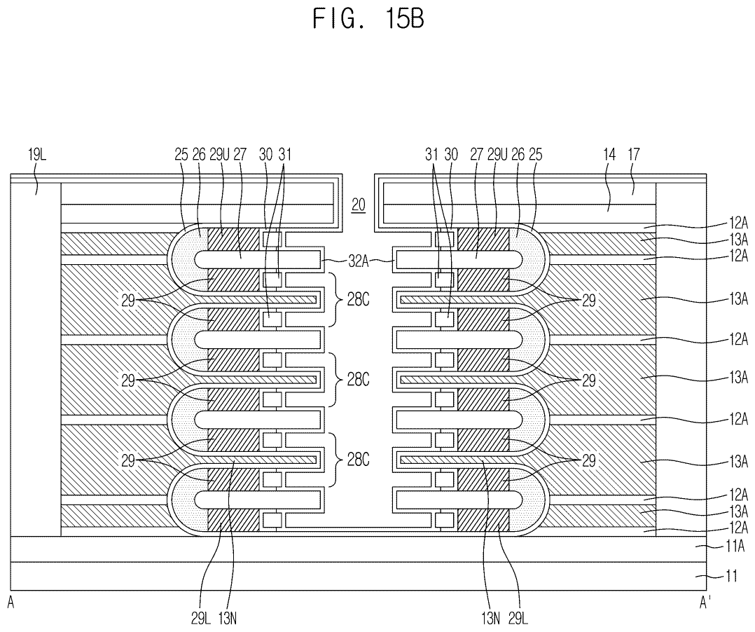

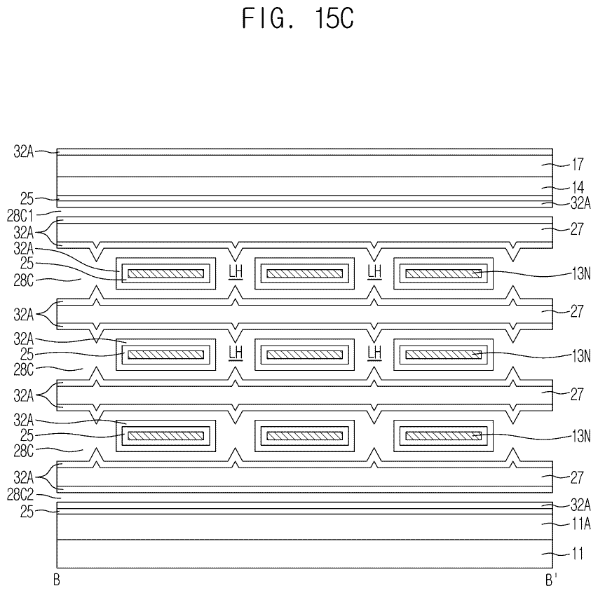

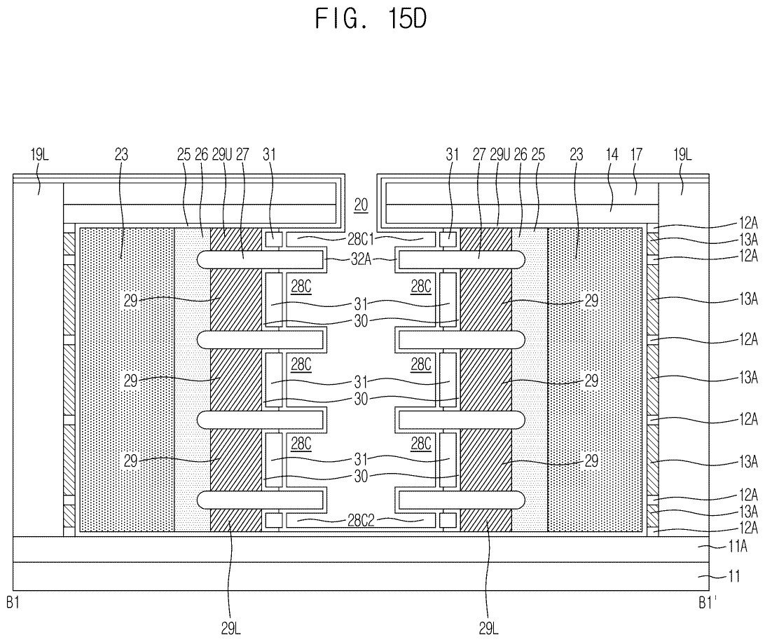

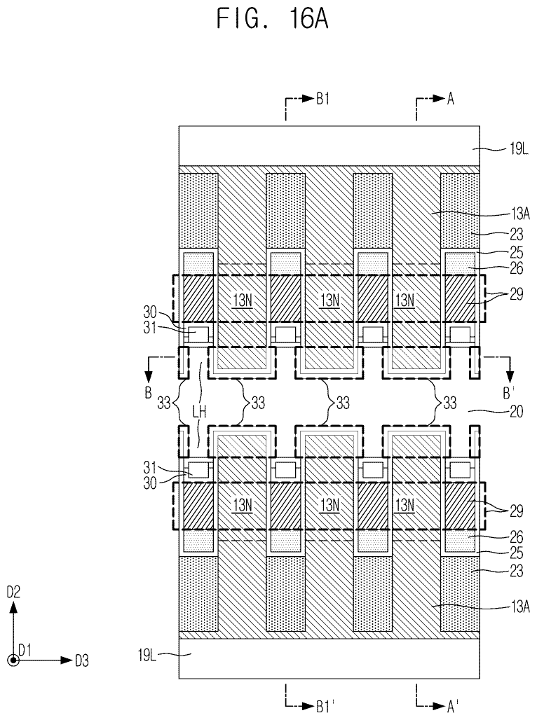

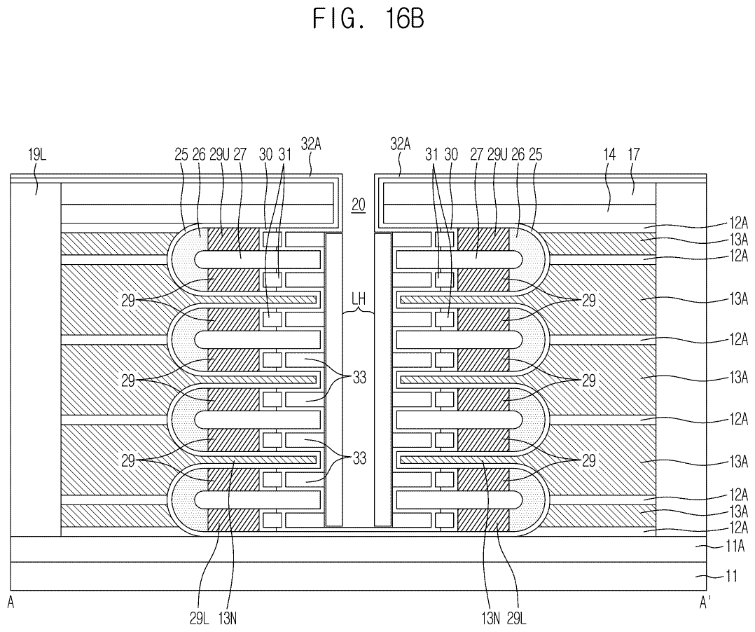

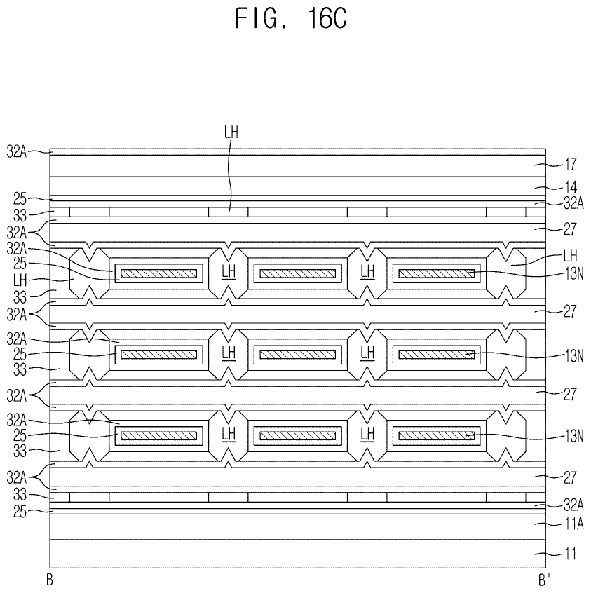

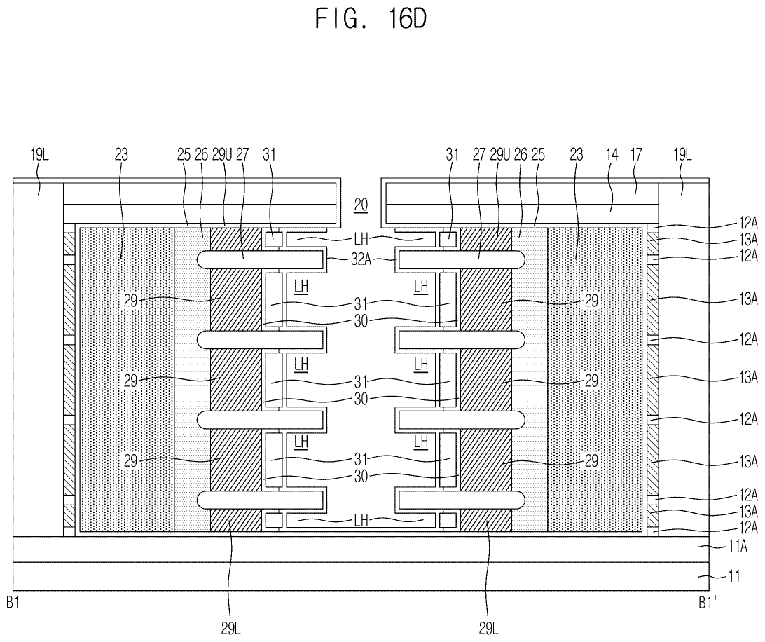

FIG. 15A is a plan view illustrating the structure at the narrow sheet level to describe an operation for forming a third sub-spacer layer 32A, which will serve as a basis for forming the third sub-spacer S3 shown in FIG. 1B. FIG. 15B is a cross-sectional view of the structure taken along line A-A′ illustrated in FIG. 15A. FIG. 15C is a cross-sectional view of the structure taken along line B-B′ illustrated in FIG. 15A. FIG. 15D is a cross-sectional view of the structure taken along line B1-B1′ illustrated in FIG. 15A.

Referring to FIGS. 15A to 15D, the third sub-spacer layer 32A may be conformally formed in the third surrounding recesses 28C. The third sub-spacer layer 32A may be formed on the first sub-spacer 30 and the second sub-spacer 31. The first sub-spacer 30 and the third sub-spacer layer 32A may be the same material, and the second sub-spacer 31 and the third sub-spacer layer 32A may be different materials. In an embodiment, the second sub-spacer 31 may include silicon oxide, and the first sub-spacer 30 and the third sub-spacer layer 32A may each include silicon nitride. The second sub-spacer 31 may be silicon oxide embedded in silicon nitride.

The third sub-spacer layer 32A may surround the narrow sheets 13N on the nano sheet dielectric layer 25. The third sub-spacer layer 32A may be formed on the upper and lower surfaces of the second inter-cell dielectric layers 27.

FIG. 16A is a plan view illustrating the structure at the narrow sheet level to describe an operation for forming fourth sub-spacers 33. FIG. 16B is a cross-sectional view of the structure taken along line A-A′ illustrated in FIG. 16A. FIG. 16C is a cross-sectional view of the structure taken along line B-B′ illustrated in FIG. 16A. FIG. 16D is a cross-sectional view of the structure taken along line B1-B1′ illustrated in FIG. 16A.

Referring to FIGS. 16A to 16D, the fourth sub-spacers 33 may be formed on the third sub-spacer layer 32A. The fourth sub-spacers 33 may fill the third surrounding recesses 28C. The fourth sub-spacers 33 may include a plurality of hole-shaped openings LH. The hole-shaped openings LH may be defined between the narrow sheets 13N at the same horizontal level. The hole-shaped openings LH may expose a portion of a surface of the third sub-spacer layer 32A.

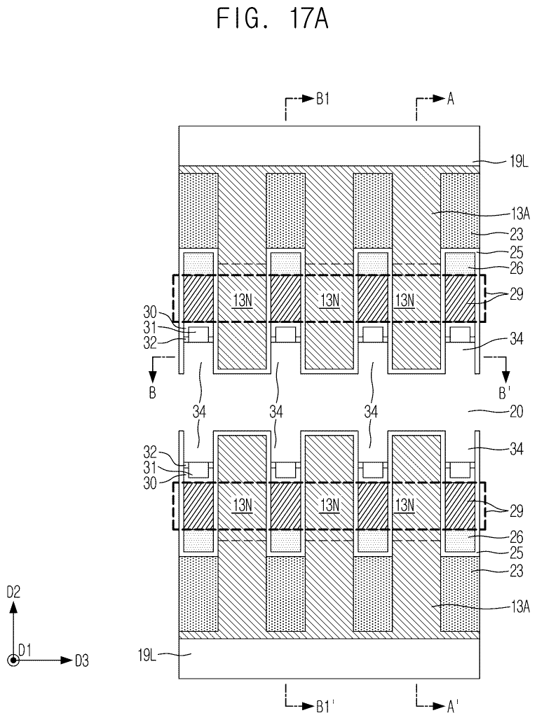

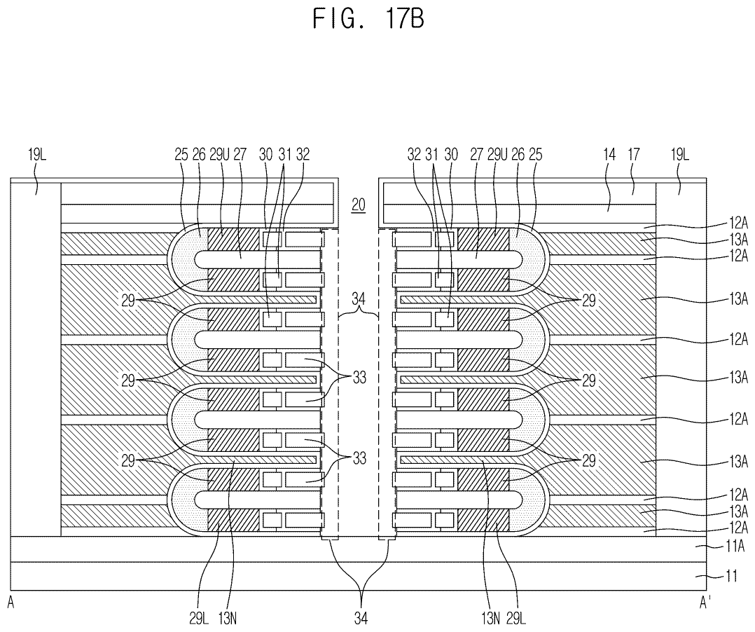

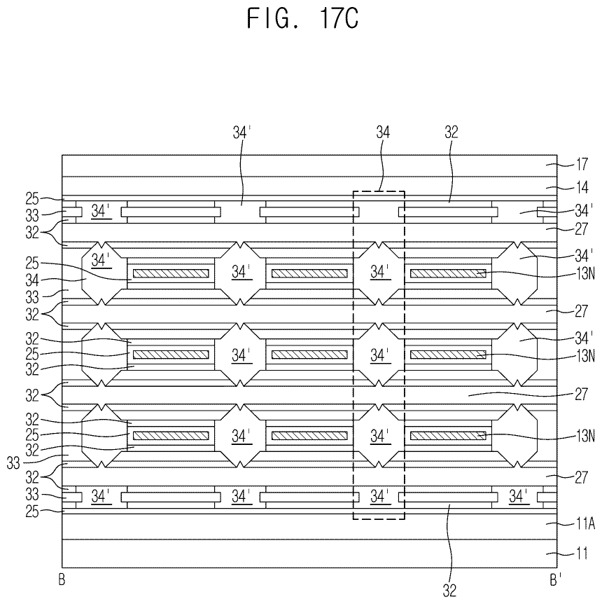

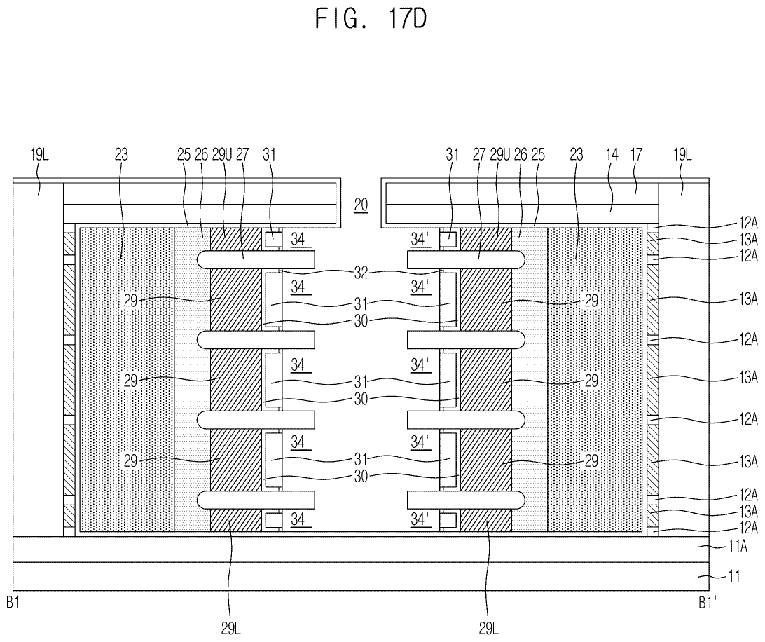

FIG. 17A is a plan view illustrating the structure at the narrow sheet level to describe an operation for forming third sub-spacers 32. FIG. 17B is a cross-sectional view of the structure taken along line A-A′ illustrated in FIG. 17A. FIG. 17C is a cross-sectional view of the structure taken along line B-B′ illustrated in FIG. 17A. FIG. 17D is a cross-sectional view of the structure taken along line B1-B1′ illustrated in FIG. 17A.

Referring to FIGS. 17A to 17D, the third sub-spacer layer 32A may be selectively recessed using the second sub-spacer 31 as a barrier, and thus the third sub-spacers 32 (e.g., the third sub-spacer S2 in FIG. 1B) may be formed. The third sub-spacers 32 may surround the surfaces of the narrow sheets 13N on the nano sheet dielectric layer 25. Outer sides of the fourth sub-spacers 33 may partially protrude by the third sub-spacers 32. The fourth sub-spacers 33 may fill the inner spaces of the third sub-spacers 32.

The third sub-spacers 32 and the fourth sub-spacers 33 may surround the fourth portions of the narrow sheets 13N at the same horizontal level on the nano sheet dielectric layer 25.

After the third sub-spacers 32 and the fourth sub-spacers 33 are formed, pillar-shaped recesses 34 may be defined. The pillar-shaped recesses 34 may include horizontal extension portions 34′. The horizontal extension portions 34′ may be defined between the narrow sheets 13N at the same horizontal level. The horizontal extension portions 34′ of the pillar-shaped recesses 34 may expose portions of surfaces of the nano sheet dielectric layer 25, the third sub-spacers 32, the fourth sub-spacers 33 and the second inter-cell dielectric layers 27.

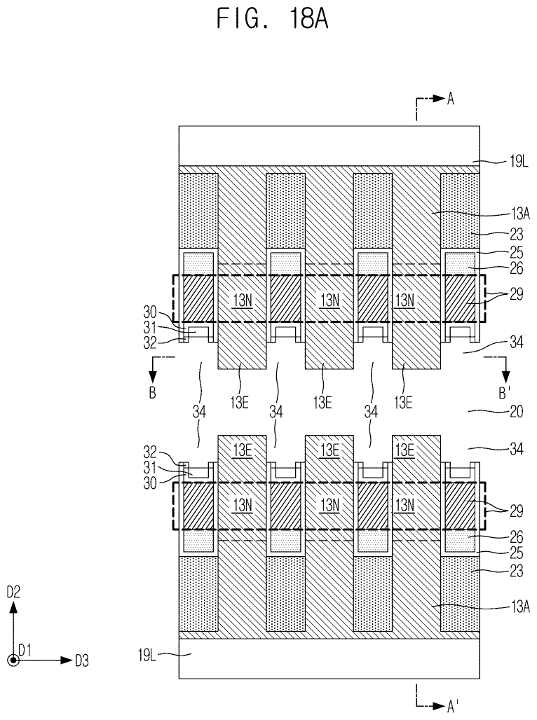

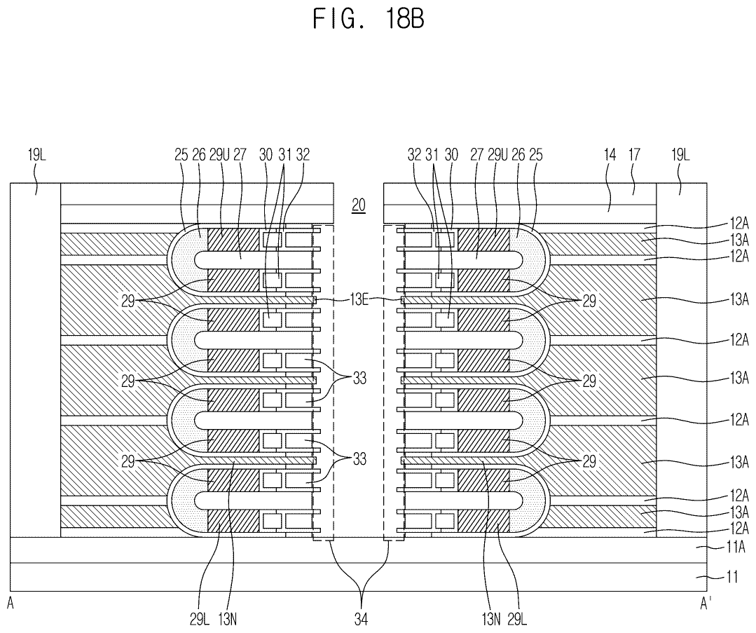

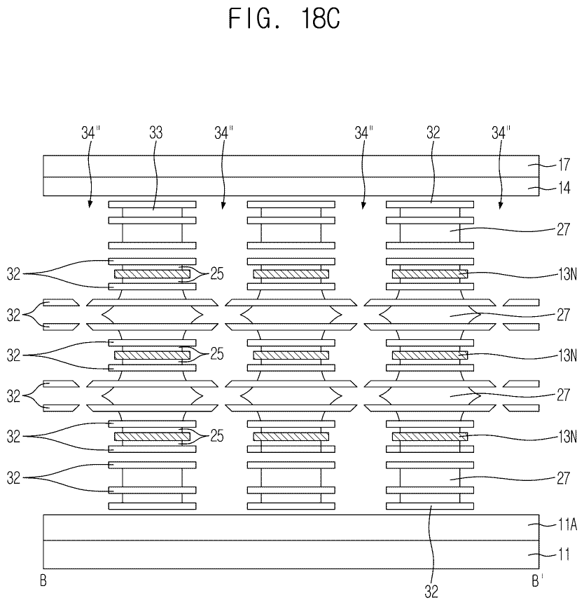

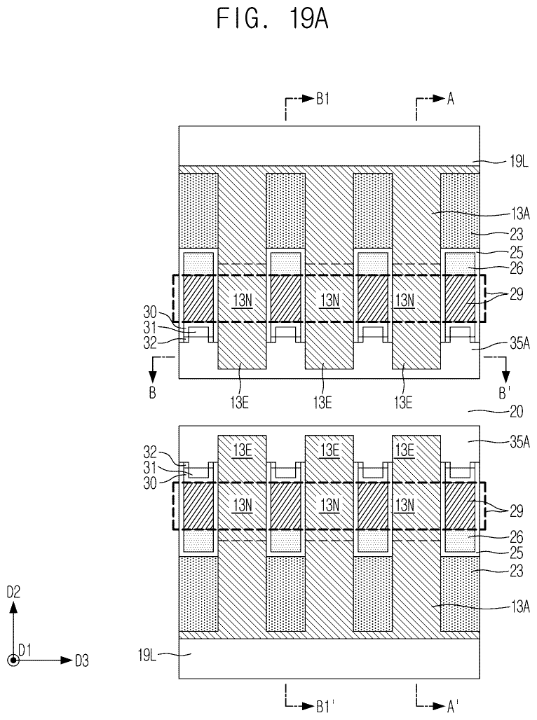

FIG. 18A is a plan view illustrating the structure at the narrow sheet level to describe an operation for exposing edges 13E of the narrow sheets 13N. FIG. 18B is a cross-sectional view of the structure taken along line A-A′ illustrated in FIG. 18A. FIG. 18C is a cross-sectional view of the structure taken along line B-B′ illustrated in FIG. 18A.

Referring to FIGS. 18A to 18C, a portion of the nano sheet dielectric layer 25 may be cut. Accordingly, the edges 13E of the narrow sheets 13N may be exposed. While the nano sheet dielectric layer 25 is cut, portions of the second inter-cell dielectric layers 27 and portions of the fourth sub-spacers 33 may be recessed. Accordingly, the size of the horizontal extension portions 34′ of the pillar-shaped recesses 34 may increase as indicated by reference numeral “34”.

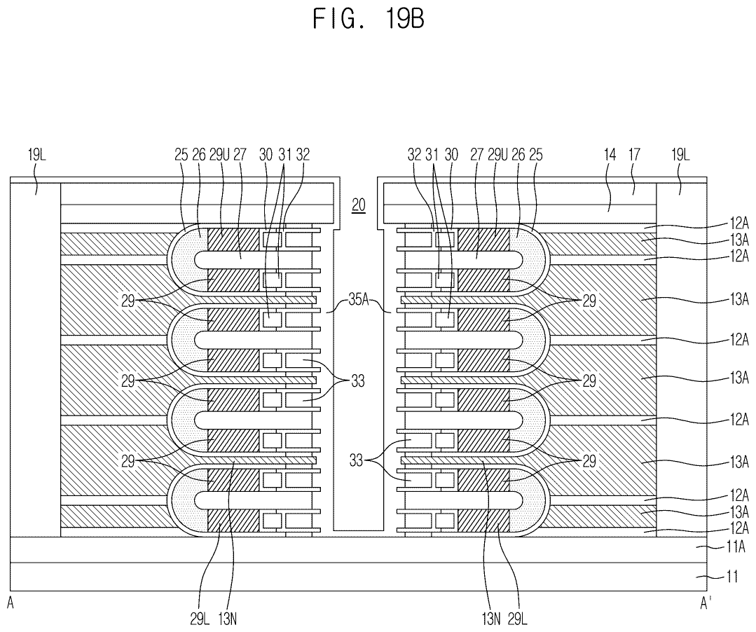

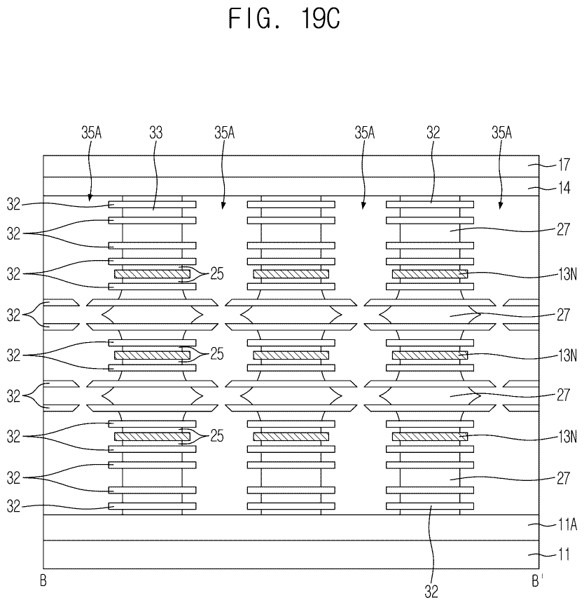

FIG. 19A is a plan view illustrating the structure at the narrow sheet level to describe an operation for forming a supporter material 35A. FIG. 19B is a cross-sectional view of the structure taken along line A-A′ illustrated in FIG. 19A. FIG. 19C is a cross-sectional view of the structure taken along line B-B′ illustrated in FIG. 19A. FIG. 19D is a cross-sectional view of the structure taken along line B1-B1′ illustrated in FIG. 19A.

Referring to FIGS. 19A to 19D, the supporter material 35A may be formed to fill the pillar-shaped recesses 34. The supporter material 35A may include a dielectric material. The supporter material 35A, the first sub-spacer 30 and the third sub-spacer 32 may be the same material. The supporter material 35A may include silicon nitride. The supporter material 35A may be conformally formed on the first linear opening 20 and fill the pillar-shaped recesses 34.

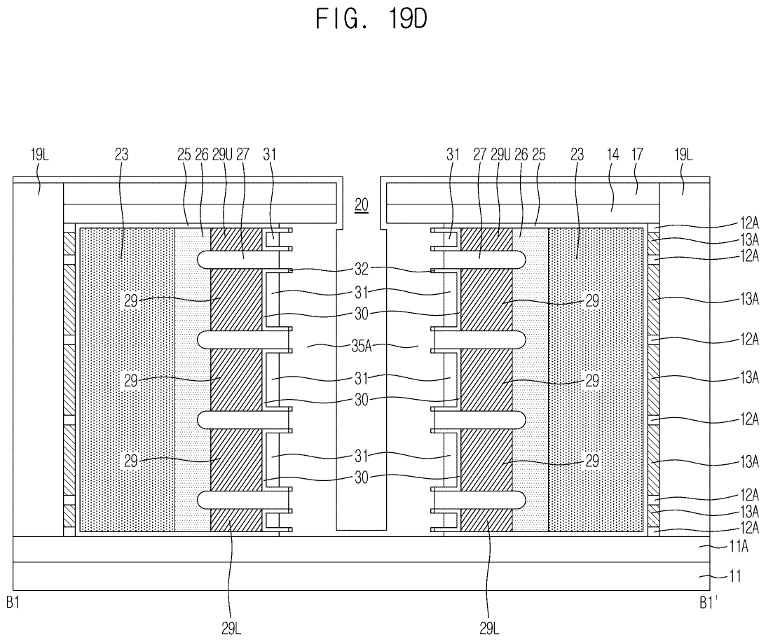

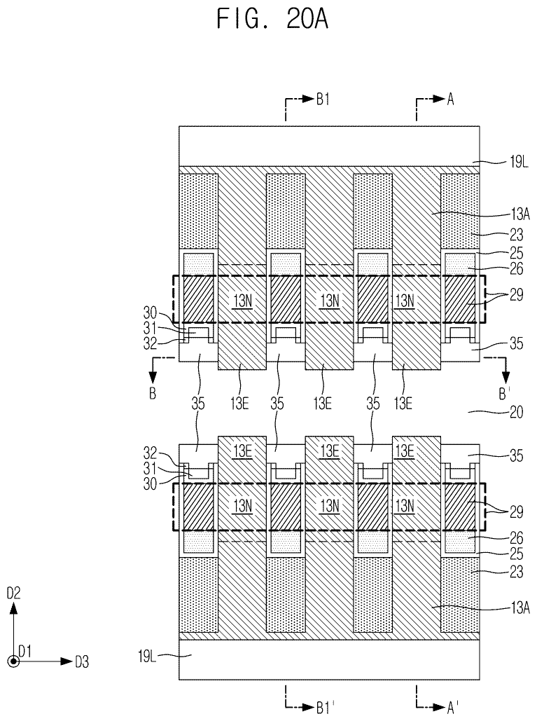

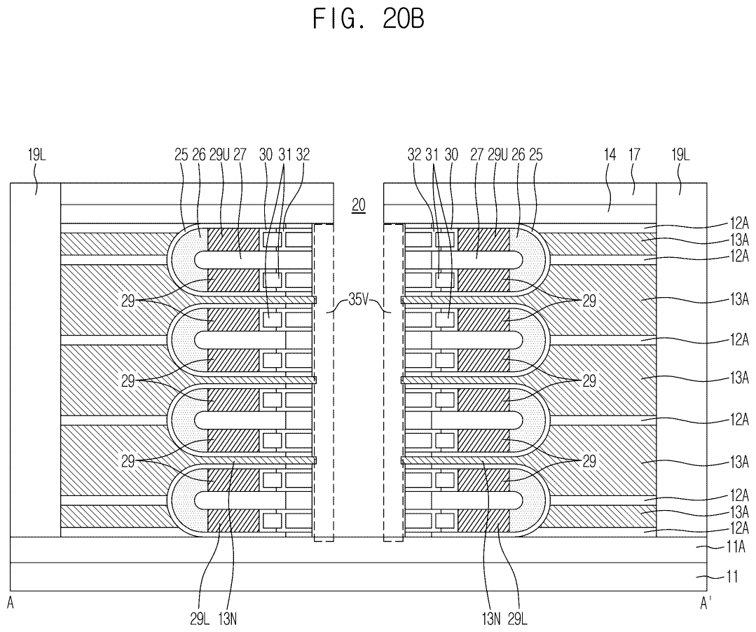

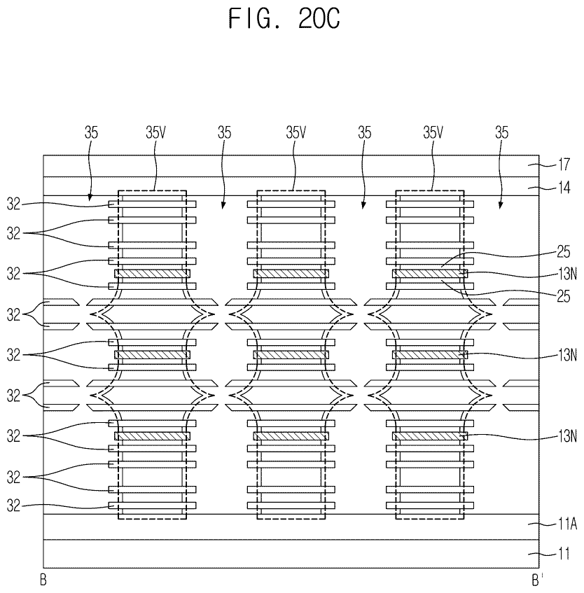

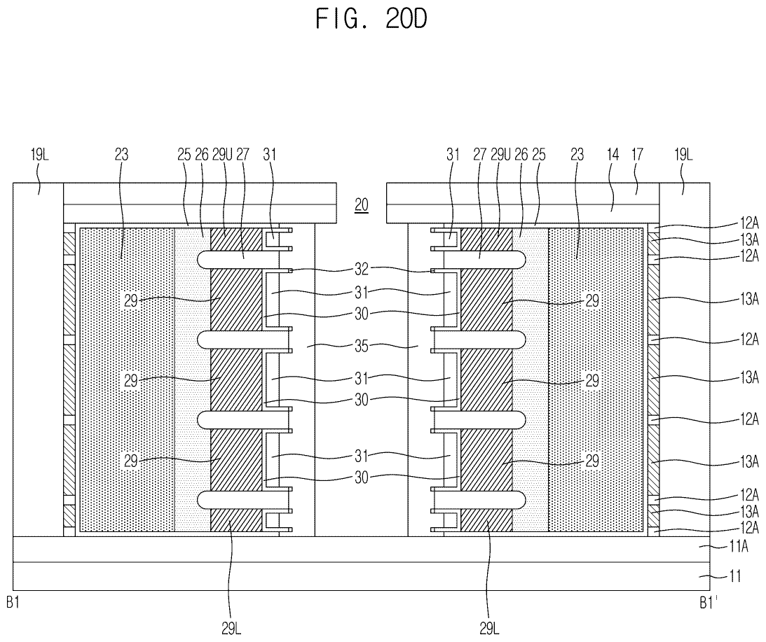

FIG. 20A is a plan view illustrating the structure at the narrow sheet level to describe an operation for forming supporters 35, which, for example, may correspond to supporters BLS shown in FIG. 2A. FIG. 20B is a cross-sectional view of the structure taken along line A-A′ illustrated in FIG. 20A. FIG. 20C is a cross-sectional view of the structure taken along line B-B′ illustrated in FIG. 20A. FIG. 20D is a cross-sectional view of the structure taken along line B1-B1′ illustrated in FIG. 20A.

Referring to FIGS. 20A to 20D, the supporters 35 may be formed to fill the pillar-shaped recesses 34. To form the supporters 35, the supporter material 35A may be recessed in the second direction D2. The supporters 35, the first sub-spacer 30 and the third sub-spacer 32 may be the same material. The supporters 35 may each include silicon nitride. Vertically-oriented recesses 35V may be defined between the supporters 35. The edges 13E of the narrow sheets 13N may be exposed by the vertically-oriented recesses 35V.

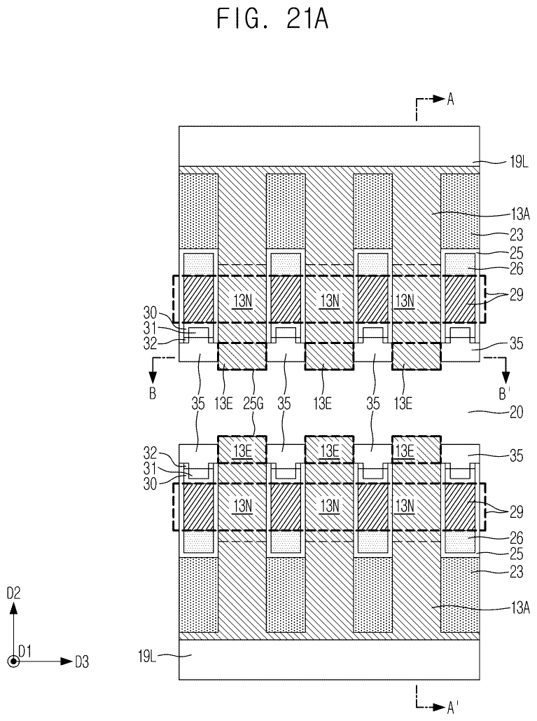

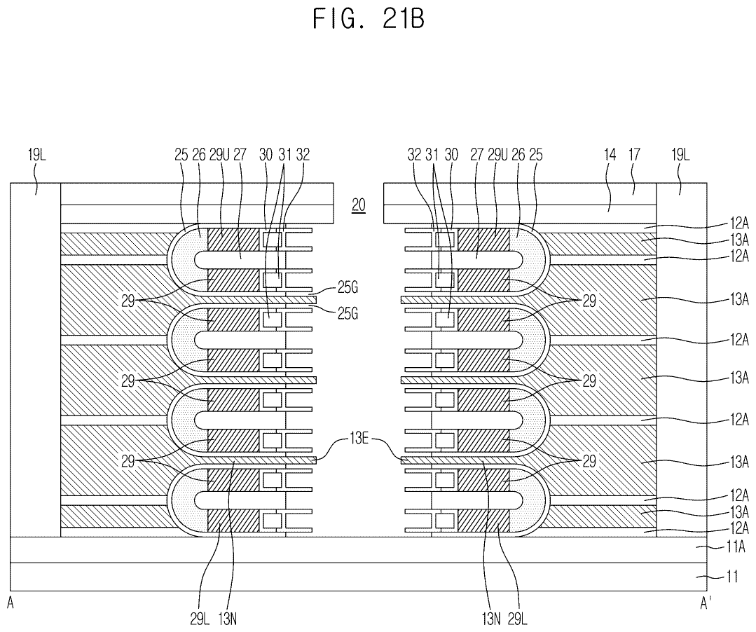

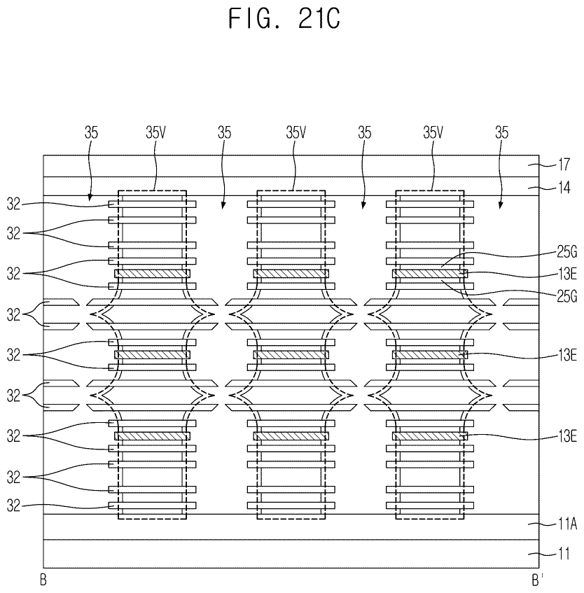

FIG. 21A is a plan view illustrating the structure at the narrow sheet level to describe an operation for exposing the edges 13E of the narrow sheets 13N. FIG. 21B is a cross-sectional view of the structure taken along line A-A′ illustrated in FIG. 21A. FIG. 21C is a cross-sectional view of the structure taken along line B-B′ illustrated in FIG. 21A. FIG. 21D is a cross-sectional view of the structure taken along line B1-B1′ illustrated in FIG. 21A.

Referring to FIGS. 21A to 21D, the fourth sub-spacers 33 may be removed.

While the fourth sub-spacers 33 are removed, portions of the nano sheet dielectric layer 25 may be recessed. After the fourth sub-spacers 33 are removed, all surfaces of the edges 13E of the narrow sheets 13N may be exposed by partial recessing spaces 25G of the nano sheet dielectric layer 25.

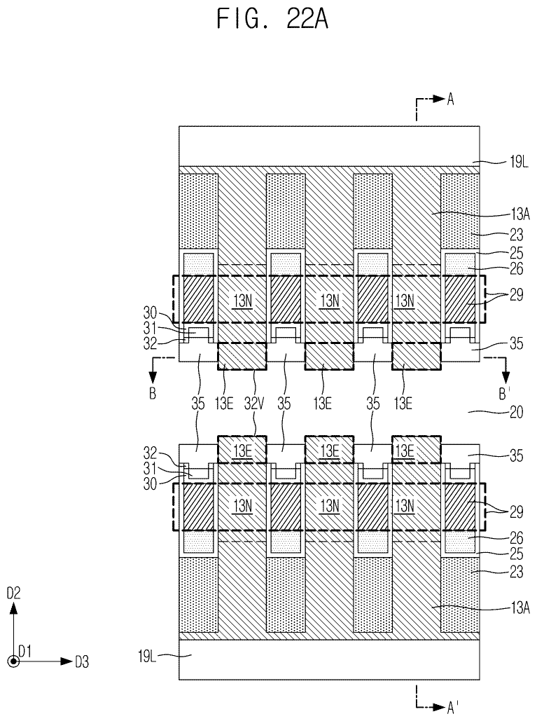

FIG. 22A is a plan view illustrating the structure at the narrow sheet level to describe an operation for exposing the edges 13E of the narrow sheets 13N. FIG. 22B is a cross-sectional view of the structure taken along line A-A′ illustrated in FIG. 22A. FIG. 22C is a cross-sectional view of the structure taken along line B-B′ illustrated in FIG. 22A.

Referring to FIGS. 22A to 22C, the third sub-spacers 32 (e.g., third sub-spacers S3 in FIG. 1B) may be selectively recessed to form fully-recessed spaces 32V. Accordingly, all the surfaces of the edges 13E of the narrow sheets 13N may be exposed by the fully-recessed spaces 32V.

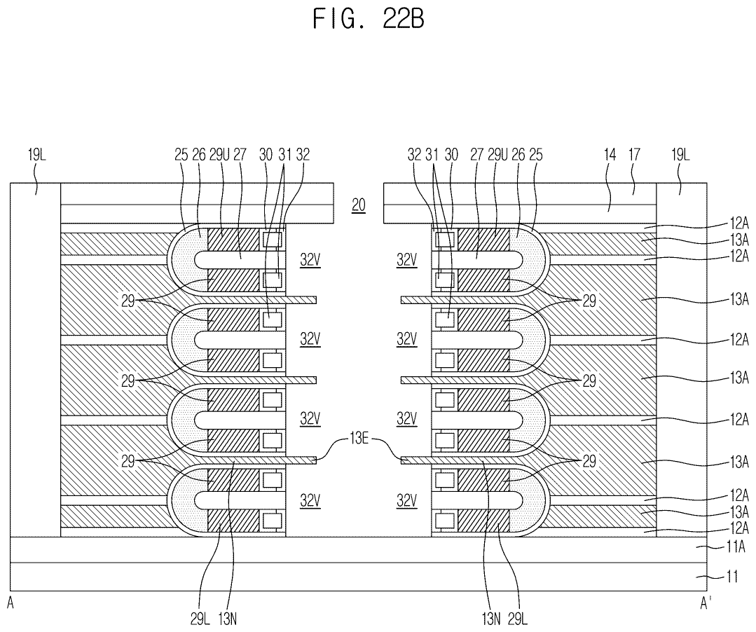

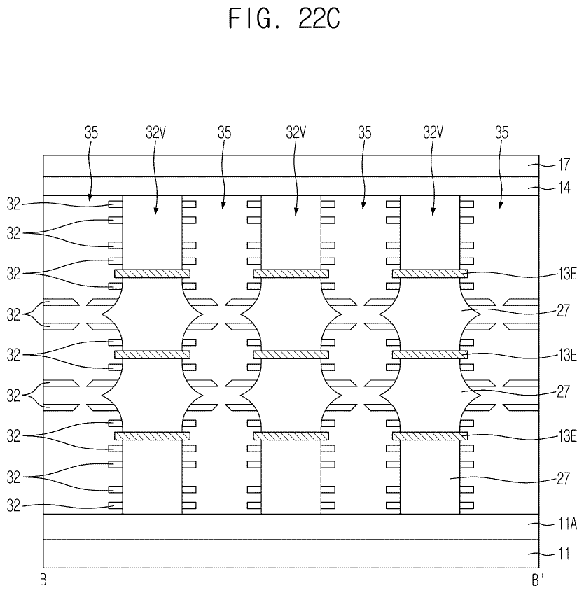

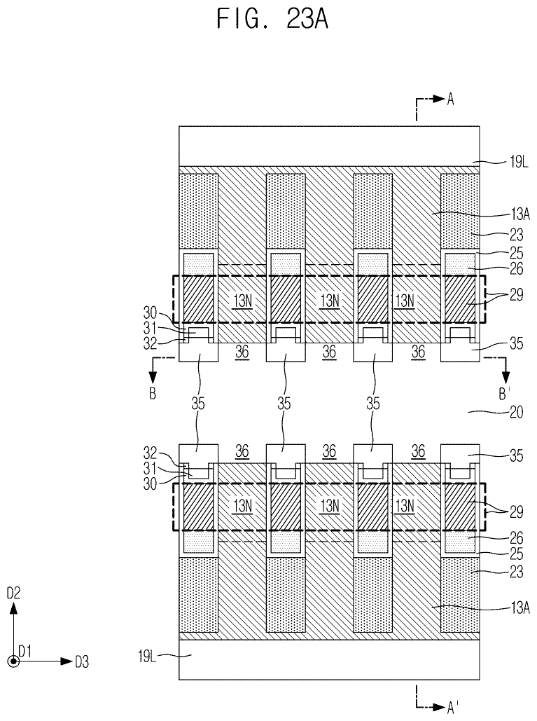

FIG. 23A is a plan view illustrating the structure at the narrow sheet level to describe a method for cutting the edges 13E of the narrow sheets 13N. FIG. 23B is a cross-sectional view of the structure taken along line A-A′ illustrated in FIG. 23A. FIG. 23C is a cross-sectional view of the structure taken along line B-B′ illustrated in FIG. 23A. Referring to FIGS. 23A to 23C, the edges 13E of the narrow sheets 13N may be cut. Accordingly, pillar-shaped openings 36 that are vertically oriented may be formed between the supporters 35.

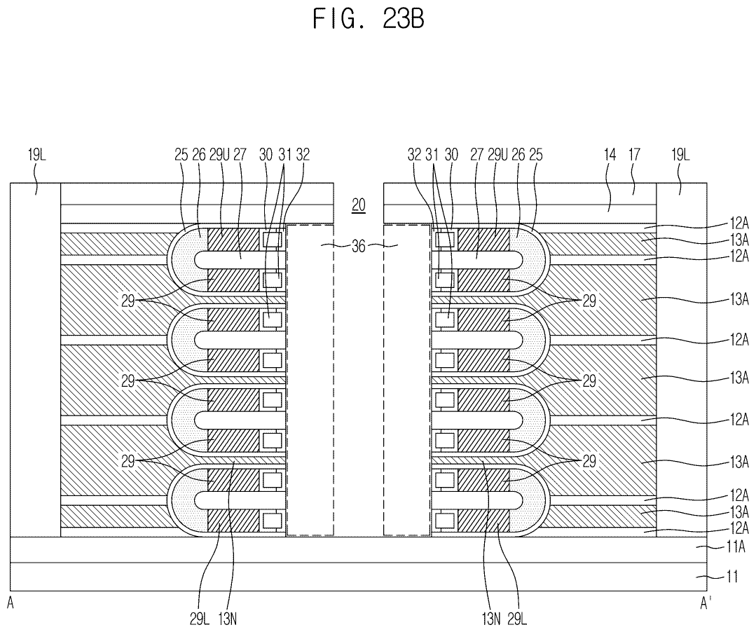

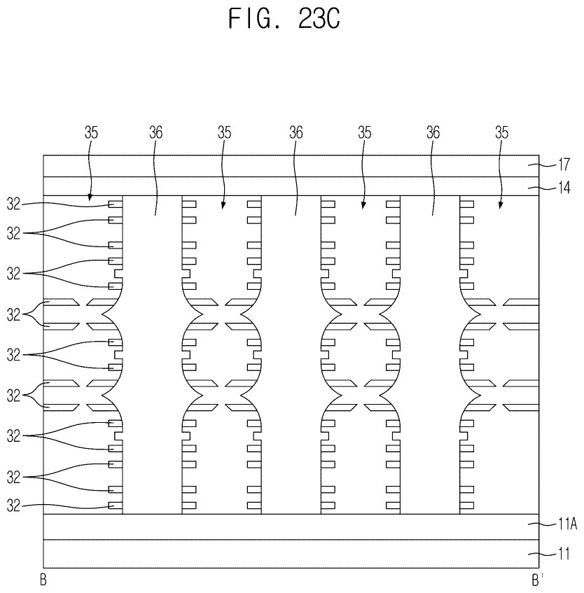

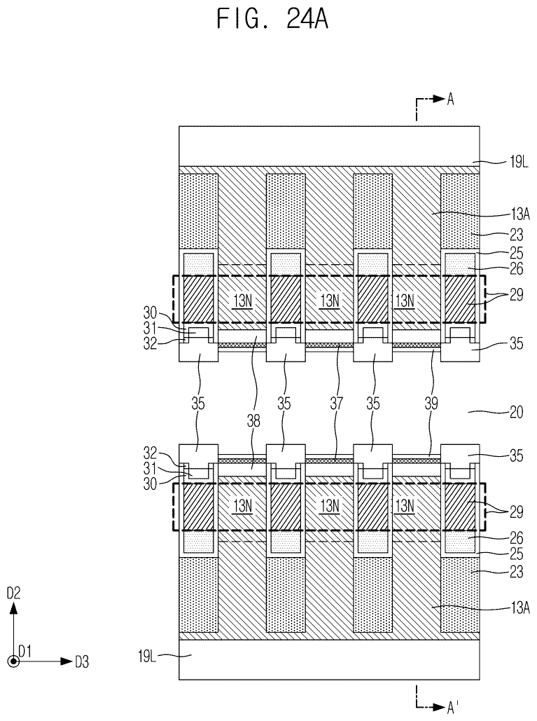

FIG. 24A is a plan view illustrating the structure at the narrow sheet level to describe an operation for forming first contact nodes 37, e.g., first contact nodes BLC in FIG. 1B. FIG. 24B is a cross-sectional view illustrating the structure taken along line A-A′ illustrated in FIG. 24A.

Referring to FIGS. 24A and 24B, the first contact nodes 37 may be formed on one side surfaces of the narrow sheets 13N. The first contact nodes 37 may have a predetermined shape, e.g., a pyramid shape or a triangular shape taken in cross-section. The first contact nodes 37 may have a different shape in another embodiment. Forming the first contact nodes 37 may include selective epitaxial growth (SEG). For example, a semiconductive material may be grown from the narrow sheets 13N through the selective epitaxial growth (SEG). The first contact nodes 37 may each include SEG Si. Because the narrow sheets 13N each include monocrystalline silicon, a silicon layer may be epitaxially grown along crystal surfaces of the side surfaces of the narrow sheets 13N.

The first contact nodes 37 may each include a dopant. When a silicon layer is grown using the selective epitaxial growth (SEG), dopants may be doped in situ. Accordingly, the first contact nodes 37 may each be a doped epitaxial layer. The first contact nodes 37 may each include an N-type dopant as the dopant. The N-type dopant may include phosphorus, arsenic, antimony, or a combination thereof. The first contact nodes 37 may include a phosphorus-doped silicon epitaxial layer formed by the selective epitaxial growth (SEG), i.e., a doped SEG SiP.

The first doped regions 38 may be formed in one side of respective ones of the narrow sheets 13N. A heat treatment process may be performed to form the first doped regions 38, and thus dopants may be diffused from the first contact nodes 37. Ohmic contact layers 39 (e.g., ohmic contact layers BLO in FIG. 1B) may be formed on the first contact nodes 37. The ohmic contact layers 39 may each include metal silicide.

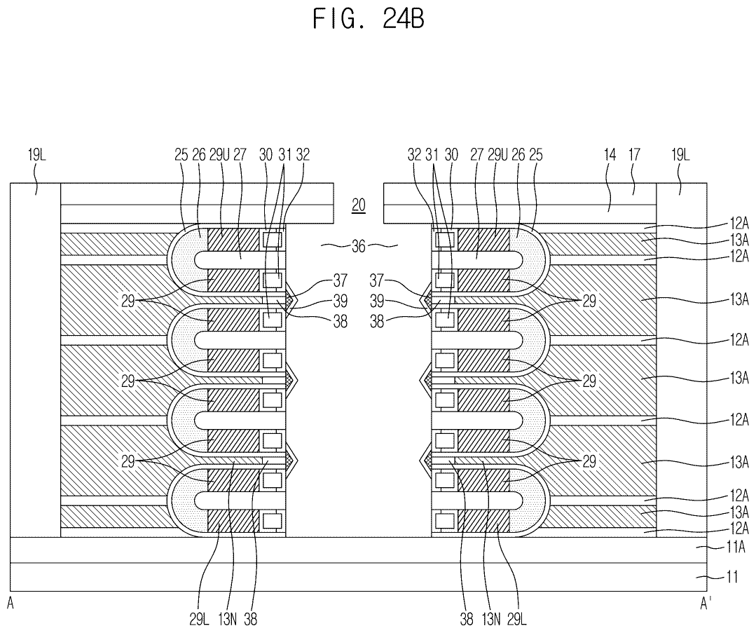

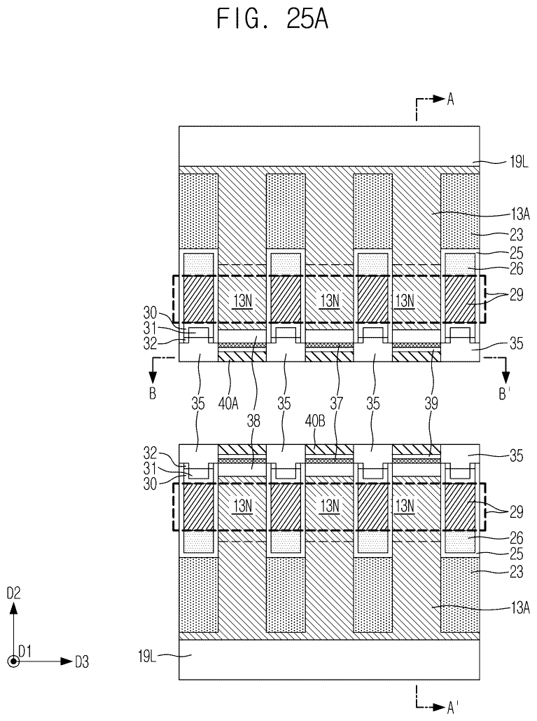

FIG. 25A is a plan view illustrating the structure at the narrow sheet level to describe an operation for forming vertical conductive lines 40, e.g., first conductive (bit) lines BL in FIG. 1B. FIG. 25B is a cross-sectional view illustrating the structure taken along line A-A′ illustrated in FIG. 25A. FIG. 25C is a cross-sectional view of the structure taken along line B-B′ illustrated in FIG. 25A.

Referring to FIGS. 25A to 25C, the vertical conductive lines 40 may be formed on the ohmic contact layers 39. The vertical conductive lines 40 may include a first vertical conductive line 40A and a second vertical conductive line 40B that are horizontally spaced apart from each other. The first and second vertical conductive lines 40A and 40B may be coupled in common to the first contact nodes 37 through the ohmic contact layers 39. The first and second vertical conductive lines 40A and 40B may be coupled in common to the narrow sheets 13N disposed in the first direction D1. The first and second vertical conductive lines 40A and 40B may each include a metal-based material. The first and second vertical conductive lines 40A and 40B may each include titanium nitride, tungsten, or a combination thereof.

Deposition and blanket etch-back processes may be performed on a vertical conductive line material to form the first and second vertical conductive lines 40A and 40B.

Bottom portions of the first and second vertical conductive lines 40A and 40B may contact the stopper layer 11A. A bridge between the substrate 11 and the first and second vertical conductive lines 40A and 40B may be prevented by the stopper layer 11A. The bottom portions of the first and second vertical conductive lines 40A and 40B may be mutually discontinuous. The first and second vertical conductive lines 40A and 40B may be disposed in the pillar-shaped openings 36 horizontally extending from the first linear opening 20. The first and second vertical conductive lines 40A and 40B may vertically extend in the first direction D1.

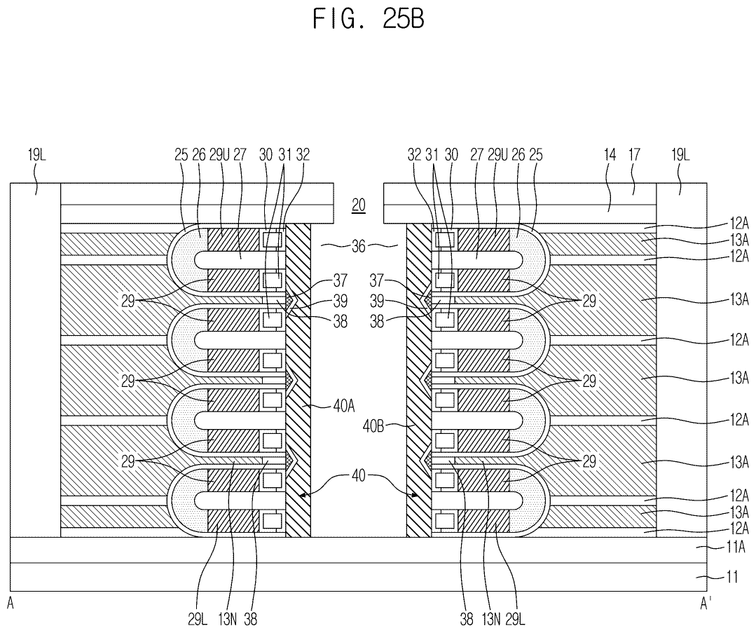

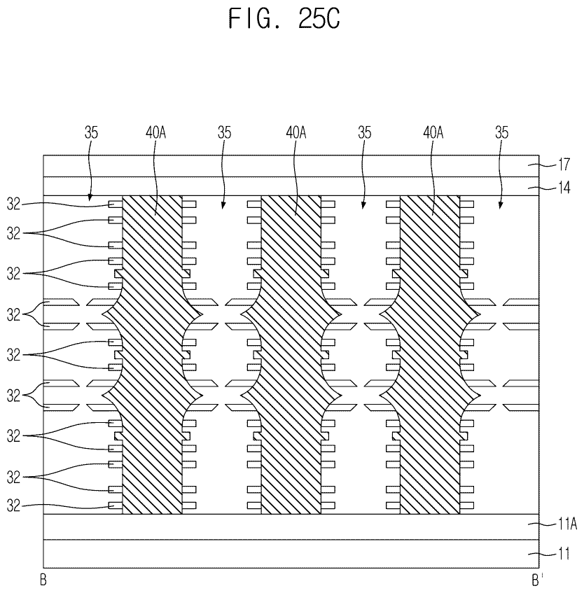

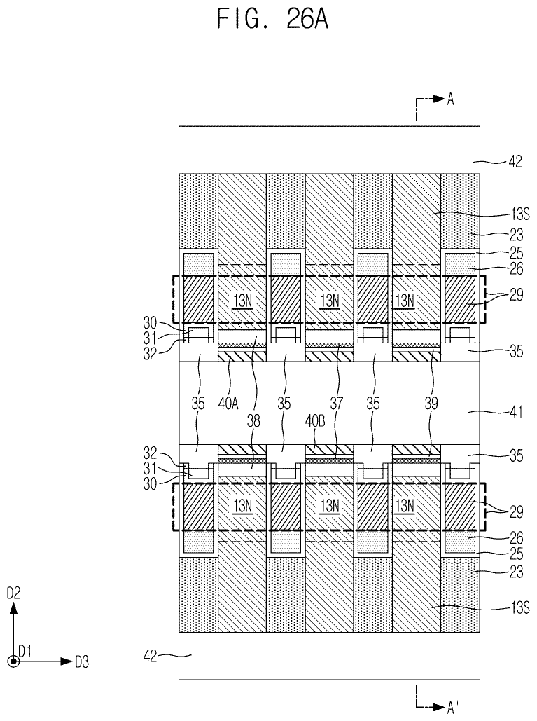

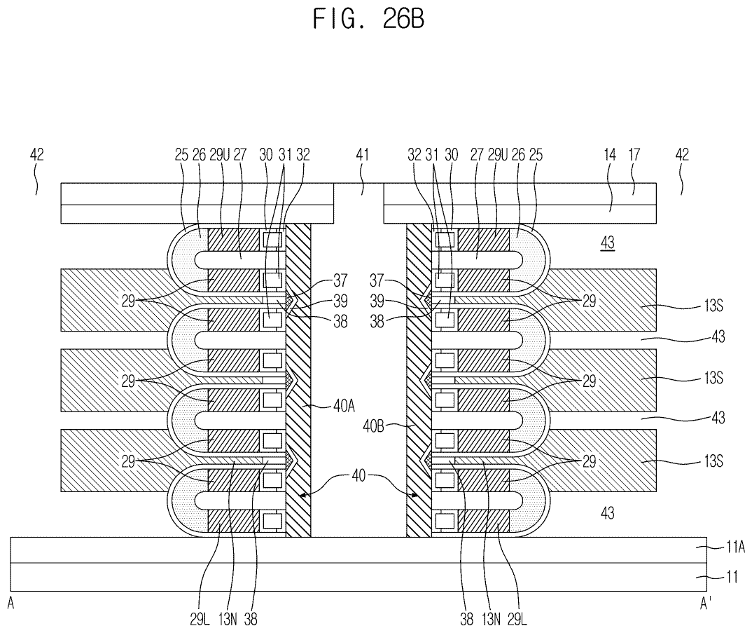

FIG. 26A is a plan view illustrating the structure at a nano sheet level to describe an operation for forming second linear openings 42. FIG. 26B is a cross-sectional view of the structure taken along line A-A′ illustrated in FIG. 26A.

Referring to FIGS. 26A and 26B, an inter-array dielectric layer 41 may be formed to fill the first linear opening 20 on the first and second vertical conductive lines 40A and 40B. The inter-array dielectric layer 41 may vertically extend in the first direction D1 and horizontally extend in the third direction D3. The first and second vertical conductive lines 40A and 40B disposed adjacent to each other in the third direction D3 (e.g., the bit lines of the different memory cell arrays) may be isolated by the inter-array dielectric layer 41. The inter-array dielectric layer 41 may include a dielectric material. The inter-array dielectric layer 41 may include silicon oxide, silicon nitride, an air gap, or a combination thereof.

Subsequently, the second linear sacrificial layer 19L may be removed. Accordingly, second linear openings 42 may be formed.

After the second linear openings 42 are formed, the first mold layers 12A may be selectively recessed through the second linear openings 42. A difference in etch selectivity between the first mold layers 12A and the original body portions 13A may be used to selectively recess the first mold layers 12A. The first mold layers 12A may be removed using a wet etch process or a dry etch process. For example, when the first mold layers 12A include silicon germanium layers and the original body portions 13A include monocrystalline silicon layers, the silicon germanium layers may be etched using an etchant or etch gas having a selectivity with respect to the monocrystalline silicon layers.

Subsequently, the original body portions 13A may be recessed. The wet etch process or the dry etch process may be used to recess the original body portions 13A. Vertical thicknesses of the original body portions 13A may be reduced, as indicated by reference numeral “13S,” to assist in the formation of data storage elements CAP in subsequent operations. Hereinafter, the original body portions having the reduced vertical thicknesses are referred to as “recessed body portions 13S”. Each of inter-body recesses 43 may be formed between the recessed body portions 13S that are vertically disposed.

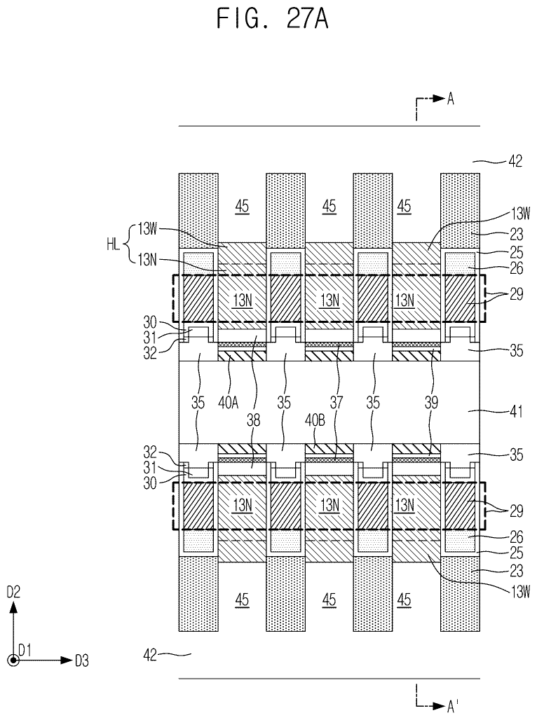

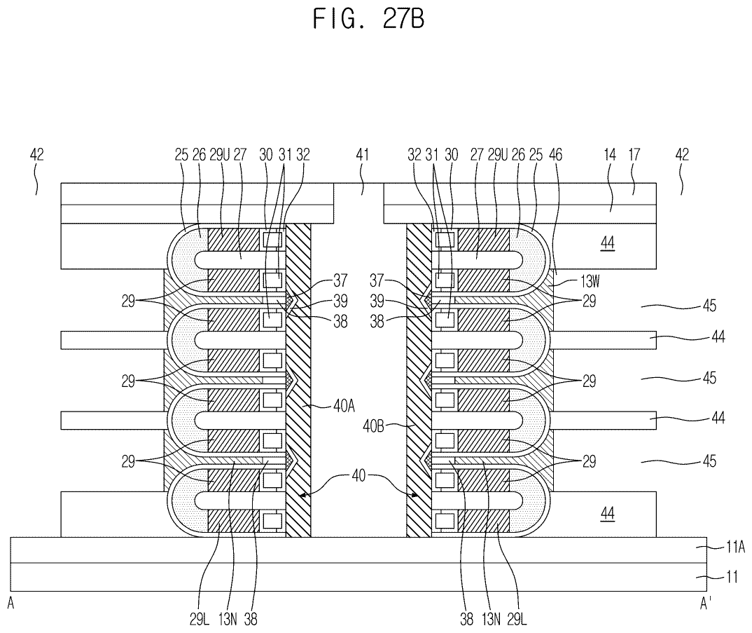

FIG. 27A is a plan view illustrating the structure at the narrow sheet level to describe an operation for forming nano sheets HL. FIG. 27B is a cross-sectional view of the structure taken along line A-A′ illustrated in FIG. 27A.

Referring to FIGS. 27A and 27B, third inter-cell dielectric layers 44 may be formed to fill the inter-body recesses 43. The third inter-cell dielectric layers 44 may each include silicon oxide.

After the third inter-cell dielectric layers 44 are formed, storage openings 45 may be formed by horizontal recessing of the recessed body portions 13S. The storage openings 45 may be referred to as “capacitor openings”. The nano sheets HL may be formed by the horizontal recessing of the recessed body portions 13S. Each of the nano sheets HL may include the narrow sheet 13N and a wide sheet 13W. The wide sheet 13W of the nano sheet HL may refer to the recessed body portion 13S remaining after the recessing.

As shown in FIG. 27B (and again in FIG. 1B), an average vertical height of the wide sheet 13W of the nano sheet HL in the first direction D1 may be greater than an average vertical height of the narrow sheet 13N. A thickness of the wide sheet 13W of the nano sheet HL may gradually increase in the second direction D2. A horizontal length of the wide sheet 13W in the second direction D2 may be less than a horizontal length of the narrow sheet 13N. The wide sheet 13W of the nano sheet HL may have a fan-like shape. The wide sheet 13W may be referred to as a “fan-shaped sheet”, and the narrow sheet 13N may be referred to as a “flat plate-shaped sheet”.

To form each of the nano sheets HL to include the wide sheet 13W, the recessed body portions 13S may be isotropically or anisotropically etched. One side of the wide sheet 13W, i.e., the side exposed by each of the storage openings 45, may have a flat shape. This one side of the wide sheet 13W may have various shapes.

Each of the nano sheets HL may include a first edge and a second edge. The first edge may refer to a portion electrically coupled to the first and second vertical conductive (bit) lines 40A and 40B, the first contact node 37 and the ohmic contact layer 39. The second edge may be a portion exposed by each of the storage openings 45.

Each of the storage openings 45 may be disposed between the third inter-cell dielectric layers 44.

In some embodiments, the horizontal recessing of the recessed body portions 13S for forming the wide sheets 13W may stop at a boundary area between the narrow sheet 13N and the wide sheet 13W.

Referring to FIGS. 5A to 27B, the narrow sheets 13N may be formed by recessing the first portions of the second mold layers 13, and the wide sheets 13W may be formed by recessing the second portions of the second mold layers 13. The wide sheets 13W may be horizontally continuous from the narrow sheets 13N.

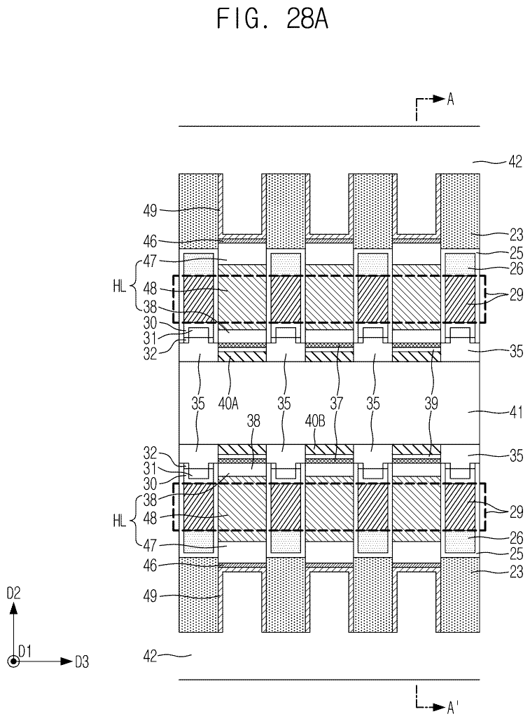

FIG. 28A is a plan view illustrating the structure at the nano sheet level to describe an operation for forming second contact nodes 46 and first electrodes 49, e.g., the second contact nodes SNC and first electrode SN of the data storage elements CAP as shown in FIG. 1B. FIG. 28B is a cross-sectional view of the structure taken along line A-A′ illustrated in FIG. 28A.

Referring to FIGS. 28A and 28B, a pre-cleaning process may be performed on one side of each of the nano sheets HL, that is, the surface of each of the wide sheets 13W.

Subsequently, the second contact nodes 46 may be formed on one side of the nano sheets HL, that is, the wide sheets 13W. Forming the second contact nodes 46 may include selective epitaxial growth (SEG). For example, a semiconductive material may be grown from the side surfaces of the wide sheets 13W through the selective epitaxial growth (SEG). The second contact nodes 46 may each include SEG Si. Because the wide sheets 13W each include monocrystalline silicon, a silicon layer may be epitaxially grown along crystal surfaces of the side surfaces of the wide sheets 13W.

The second contact nodes 46 may each include a dopant. When the silicon layer is grown using the selective epitaxial growth (SEG), dopants may be doped in situ. Accordingly, the second contact nodes 46 may each be a doped epitaxial layer. The second contact nodes 46 may each include an N-type dopant as the dopant. The N-type dopant may include phosphorus, arsenic, antimony, or a combination thereof. The second contact nodes 46 may include a phosphorus-doped silicon epitaxial layer formed by the selective epitaxial growth (SEG), i.e., a doped SEG SiP.

Because the second contact nodes 46 are formed using the selective epitaxial growth (SEG), void-free or seam-free second contact nodes 46 may be formed. Because the second contact nodes 46 are formed using the selective epitaxial growth (SEG), a process for forming the second contact nodes 46 may be simplified.

Each of the second contact nodes 46 may be disposed between the third inter-cell dielectric layers 44 that are vertically stacked.

Second doped regions 47 (e.g., source/drain regions DR in FIG. 1B) may be formed in the wide sheets 13W of the nano sheets HL. A heat treatment process may be performed to form the second doped regions 47, and thus dopants may be diffused from the second contact nodes 46.

Each of the nano sheets HL may include the first doped region 38, the second doped region 47, and a channel 48, i.e., includes the structure of the nano sheet HL shown in FIG. 1B. The channel 48 may be defined between the first doped region 38 and the second doped region 47. The first doped region 38 and the channel 48 may be formed in each of the narrow sheets 13N, and the second doped region 47 may be formed in each of the wide sheets 13W. A portion of each of the second doped regions 47 may extend into the narrow sheet 13N. One side of each of the second doped regions 47 of the nano sheets HL may be coupled to the channel 48, and the other side of each of the second doped regions 47 of the nano sheets HL may be coupled to the second contact node 46.

In some embodiments, an ohmic contact layer including metal silicide may be further formed after the second contact nodes 46 are formed.

Subsequently, the first electrodes 49 of a data storage element CAP may be formed on the second contact nodes 46. The first electrodes 49 may each have, for example, a horizontally-oriented cylindrical shape. Each of the first electrodes 49 may be disposed in a corresponding one of the storage openings 45. The first electrodes 49 disposed adjacent to each other in the second direction D2 may be spaced apart from each other by the second linear openings 41. The first electrodes 49, disposed adjacent to each other in the third direction D3, may be spaced apart from each other by the first inter-cell dielectric layers 23. The first electrodes 49, disposed adjacent to each other in the first direction D1, may be spaced apart from each other by the third inter-cell dielectric layers 44. Forming the first electrodes 49 may include depositing a metal material, gap-filling a sacrificial material, and isolating the metal material in a vertical/horizontal direction. The sacrificial material may include oxide or polysilicon.

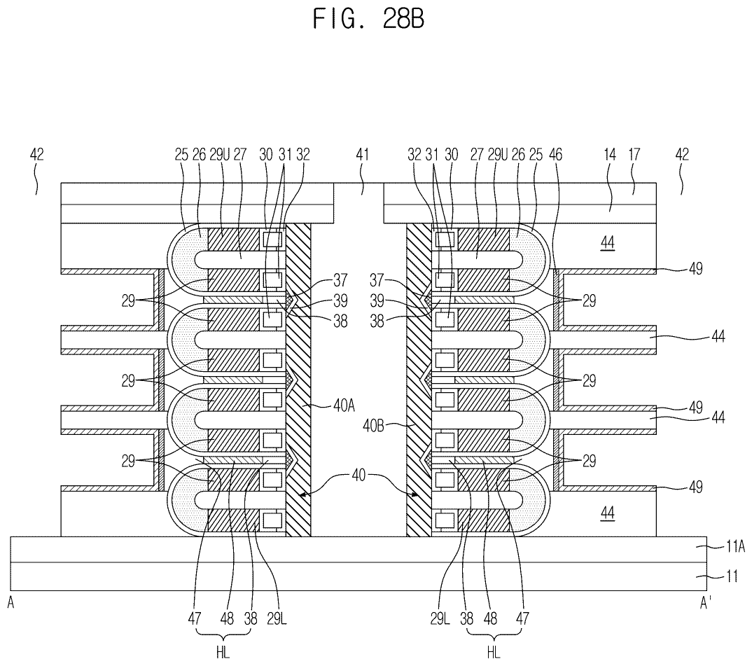

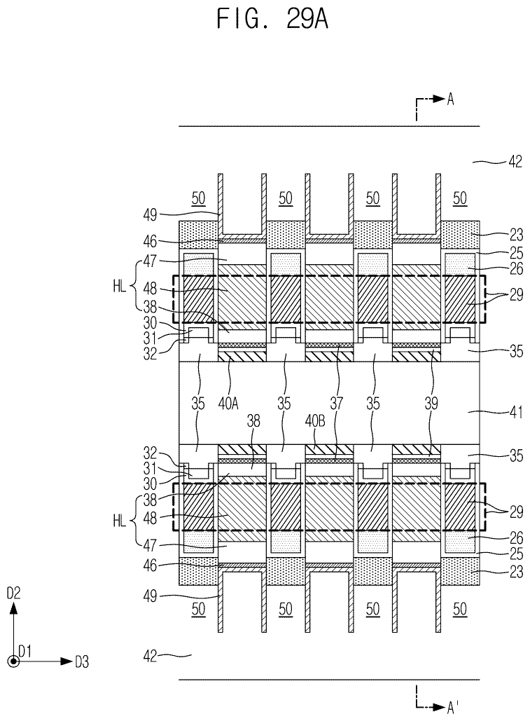

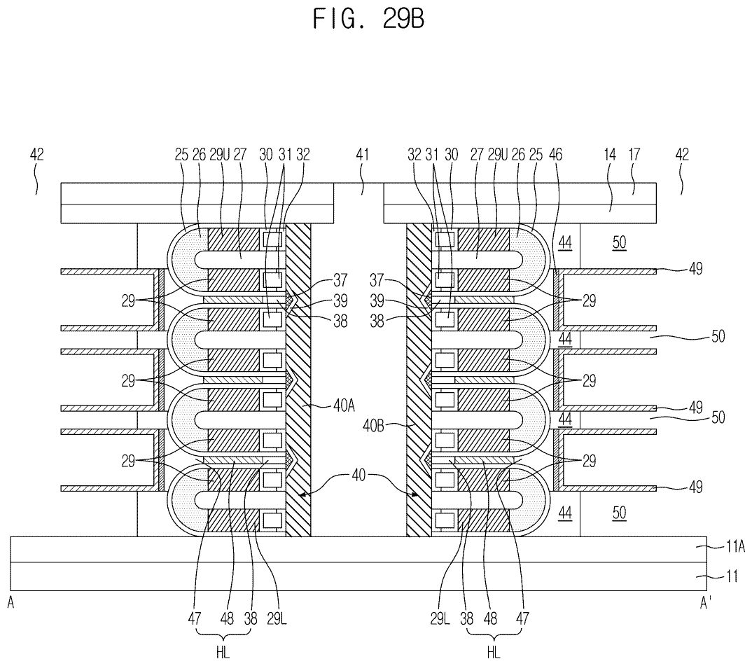

FIG. 29A is a plan view illustrating the structure at the nano sheet level to describe an operation for recessing the first and third inter-cell dielectric layers 23 and 44. FIG. 29B is a cross-sectional view of the structure taken along line A-A′ illustrated in FIG. 29A.

Referring to FIGS. 29A and 29B, portions of the first and third inter-cell dielectric layers 23 and 44 may be horizontally recessed (refer to reference numeral “50”). Accordingly, outer walls of the first electrodes 49 may be partially exposed, to allow for formation of the dielectric and second electrodes of the data storage elements. The first electrodes 49 may each have a semi-cylindrical shape. Horizontal recess depths of the first and third inter-cell dielectric layers 23 and 44 may be depths that do not expose the second contact nodes 46.

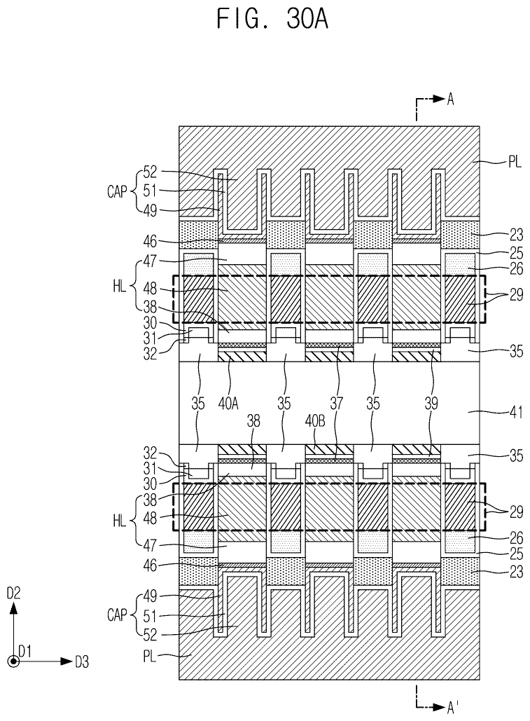

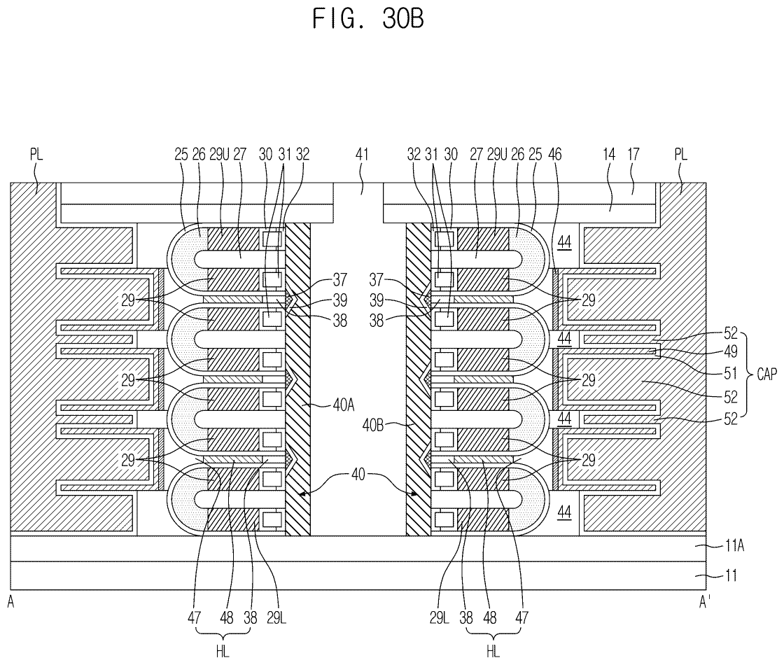

FIG. 30A is a plan view illustrating the structure at the nano sheet level to describe an operation for forming second electrodes 52 of the data storage element. FIG. 30B is a cross-sectional view of the structure taken along line A-A′ illustrated in FIG. 30A.

Referring to FIGS. 30A and 30B, a dielectric layer 51 and the second electrode 52 may be sequentially formed on the first electrodes 49. The first electrode 49, the dielectric layer 51 and the second electrode 52 may be the data storage element CAP shown, for example, in FIG. 1B.

The first electrode 49 may include an inner space and a plurality of outer surfaces, and the inner space of the first electrode 49 may include a plurality of inner surfaces. The outer surfaces of the first electrode 49 may include a vertical outer surface and a plurality of horizontal outer surfaces. The vertical outer surface of the first electrode 49 may vertically extend in the first direction D1, and the horizontal outer surfaces of the first electrode 49 may horizontally extend in the second direction D2 or the third direction D3. The inner space of the first electrode 49 may be a three-dimensional space. The dielectric layer 51 may conformally cover the inner surfaces and horizontal outer surfaces of the first electrode 49. The second electrode 52 may be disposed on the inner space and horizontal outer surfaces of the first electrode 49 on the dielectric layer 51. Among the outer surfaces of the first electrode 49, the vertical outer surface may be electrically coupled to the nano sheet HL and the second contact node 46.

The first electrode 49 may have a predetermined shape, e.g., a semi-cylindrical shape. The semi-cylindrical shape of the first electrode 49 may include cylindrical inner surfaces and semi-cylindrical outer surfaces. The dielectric layer 51 and the second electrode 52 may be disposed on the cylindrical inner surfaces of the first electrode 49. A portion of the dielectric layer 51 and a portion of the second electrode 52 may extend to be disposed on the semi-cylindrical outer surfaces of the first electrode 49. The second electrode 52 may vertically extend in the first direction D1.

The first electrode 49 and the second electrode 52 may each include metal, noble metal, metal nitride, conductive metal oxide, conductive noble metal oxide, metal carbide, metal silicide, or a combination thereof. For example, the first electrode 49 and the second electrode 52 may each include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof. The second electrode 52 may also include a combination of a metal-based material and a silicon-based material. For example, the second electrode 52 may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material filling the inner space of the first electrode 49, titanium nitride (TiN) may serve as the second electrode 52 of the data storage element CAP, and tungsten nitride may be a low-resistivity material.

The dielectric layer 51 may be referred to as a “capacitor dielectric layer” or a “memory layer”. The dielectric layer 51 may include silicon oxide, silicon nitride, a high-k material, a ferroelectric material, an antiferroelectric material, a perovskite material, or a combination thereof. The dielectric layer 51 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 51 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) a stack, HZHZ(HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack.

In some embodiments, an interface control layer may be further formed between the first electrode 49 and the dielectric layer 51 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 52 and the dielectric layer 51.

According to the above-described embodiment, the first and second vertical conductive lines 40A and 40B may be formed by being self-aligned with the supporters 35 without high aspect ratio etch. Accordingly, a memory cell array including memory cells having the same dimension may be formed. In addition, according to the above-described embodiment, costs may be reduced because the high aspect ratio etch is not performed to form the first and second vertical conductive lines 40A and 40B.

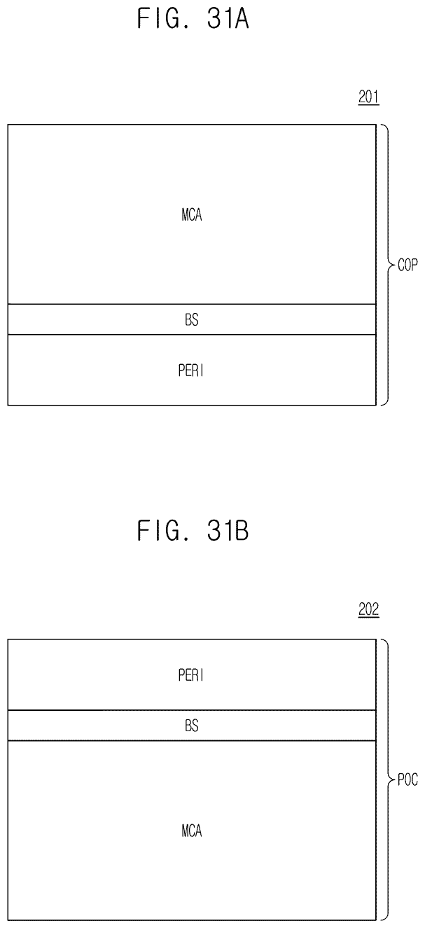

FIGS. 31A and 31B are schematic cross-sectional views of a semiconductor device 201 in accordance with embodiments of the present disclosure.

Referring to FIG. 31A, the semiconductor device 201 may include a memory cell array MCA, a peripheral circuit portion PERI, and a bonding interface BS. The memory cell array MCA may correspond to any of the embodiments of the memory cell arrays previously discussed, e.g., may correspond to one or more of the memory cell arrays shown, for example, in FIG. 3A. The bonding interface BS may be disposed between the memory cell array MCA and the peripheral circuit portion PERI.

In the semiconductor device 201, the memory cell array MCA may be disposed at a level higher than the peripheral circuit portion PERI. The semiconductor device 201 may be referred to as a “Cell array Over Peri (COP) structure” or a “Peri Under Cell array (PUC) structure”. The memory cell array MCA may include a substrate on which back-grinding is performed and an array of memory cells. For example, as described with reference to FIGS. 30A and 30B, after the data storage elements CAP are formed, the substrate 11 may be flipped over through a wafer-flipping, and then a back side of the substrate 11 may be partially grinding.

Referring to FIG. 31B, a semiconductor device 202 may include a memory cell array MCA, a peripheral circuit portion PERI, and a bonding interface BS. The memory cell array MCA may correspond to any of the embodiments of the memory cell arrays previously discussed, e.g., may correspond to one or more of the memory cell arrays shown, for example, in FIG. 3A. The bonding interface BS may be disposed between the memory cell array MCA and the peripheral circuit portion PERI. In the semiconductor device 202, the memory cell array MCA may be disposed at a level lower than the peripheral circuit portion PERI. The semiconductor device 202 may be referred to as a “Peri Over Cell array (POC) structure” or a “Cell array Under Peri (CUP) structure”. Forming the peripheral circuit portion PERI may include forming a plurality of control circuits on a peripheral circuit substrate and forming multi-level interconnection on the control circuits.

In FIG. 31A and FIG. 31B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device 201 illustrated in FIG. 31A may perform the wafer flip on the substrate on which the memory cell array is formed so that the cell bonding pad and the peripheral circuit bonding pad face each other, after the cell bonding pad and the peripheral circuit bonding pad are formed. The semiconductor device 202 illustrated in FIG. 31B may perform the wafer flip on the substrate on which the peripheral circuit portion is formed so that the cell bonding pad and the peripheral circuit bonding pad face each other, after the cell bonding pad and the peripheral circuit bonding pad are formed.

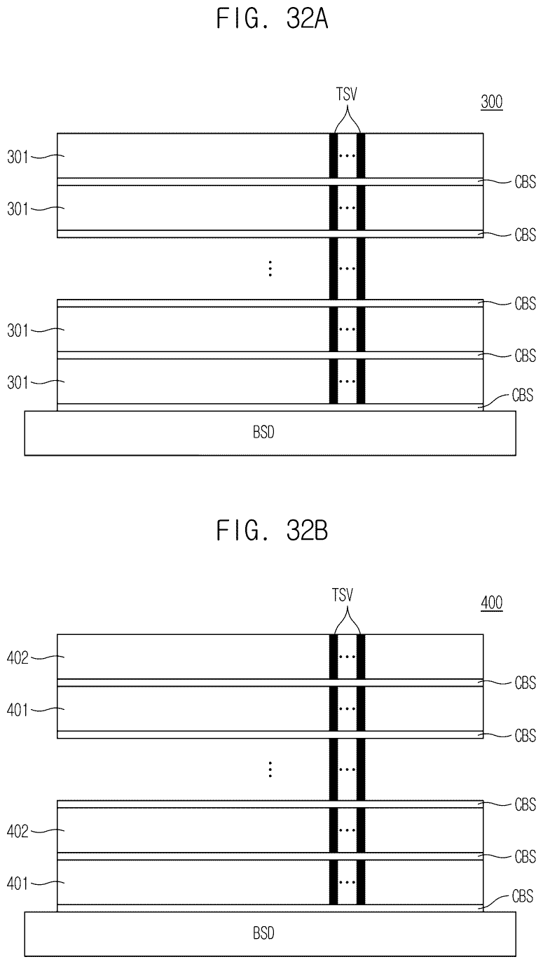

FIGS. 32A and 32B illustrate various views illustrating a stack assembly in accordance with an embodiment of the present disclosure.

Referring to FIG. 32A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to embodiments described above. Each of the second semiconductor dies 301 may include structures in which a memory cell array and a peripheral circuit portion are stacked, for example, the semiconductor device 201 illustrated in FIG. 31A or the semiconductor device 202 illustrated in FIG. 31B. The logic circuits of the first semiconductor die BSD may be different from the peripheral circuit portions of the second semiconductor dies 301. The second semiconductor dies 301 may be electrically coupled to each other by through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, wafer-flipping and back-grinding of the second semiconductor dies 301 may be performed to form the bonding interfaces CBS.

Referring to FIG. 32B, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second semiconductor dies 401 and each of the third semiconductor dies 402 may include memory cell arrays according to embodiments described above. The second semiconductor dies 401 and the third semiconductor dies 402 may have different structures.

Each of the second semiconductor dies 401 may include structures in which a memory cell array and a peripheral circuit portion are stacked, for example, the semiconductor device 201 illustrated in FIG. 31A. Each of the third semiconductor dies 402 may include structures in which a memory cell array and a peripheral circuit portion are stacked, for example, the semiconductor device 202 illustrated in FIG. 31B.

In some embodiments, each of the second semiconductor dies 401 may include the semiconductor device 202 illustrated in FIG. 31B, and each of the third semiconductor dies 402 may include the semiconductor device 201 illustrated in FIG. 31A.

The logic circuits of the first semiconductor die BSD may be different from the peripheral circuit portions of the second and third semiconductor dies 401 and 402. The second and third semiconductor dies 401 and 402 may be electrically coupled to each other by through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, wafer-flipping and back-grinding processes may be performed to form the bonding interface CBS. For example, wafer-flipping and back-grinding of the second semiconductor dies 401 and/or the third semiconductor dies 402 may be performed.

The stack assemblies 300 and 400 illustrated in FIGS. 32A and 32B may be high bandwidth memories.

According to the aforementioned embodiments of the present disclosure, vertical conductive lines may be formed by being self-aligned with supporters without high aspect ratio etch.

According to the aforementioned embodiments of the present disclosure, a memory cell array including memory cells having the same dimension may be formed.

According to the aforementioned embodiments of the present disclosure, costs may be reduced because high aspect ratio etch is not performed to form vertical conductive lines.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
a horizontal arrangement of switching elements including nano sheets and a horizontal conductive line surrounding the nano sheets;
vertical conductive lines each coupled to a corresponding one of first edges of the nano sheets in the horizontal arrangement;
data storage elements each coupled to a corresponding one of second edges of the nano sheets in the horizontal arrangement;
supporters disposed between the vertical conductive lines;
a first spacer disposed between the data storage elements and the horizontal conductive line, and surrounding the nano sheets; and
a second spacer having a multi-layer structure, the second spacer being disposed between the vertical conductive lines and the horizontal conductive line and surrounding the nano sheets.

2. The semiconductor device of claim 1, wherein:
the vertical conductive lines are self-aligned with the supporters and the second spacer, and
the supporters are vertically oriented in an extending direction of the vertical conductive lines.

3. The semiconductor device of claim 1, wherein each of the supporters includes a low-k material, silicon carbon oxide, silicon nitride, an air gap, or a combination thereof.

4. The semiconductor device of claim 1, wherein the multi-layer structure of the second spacer includes:
a first sub-spacer contacting a corresponding one of the horizontal conductive line and surrounding a corresponding one of the nano sheets;
a pair of third sub-spacers contacting the first sub-spacer and a corresponding one of the vertical conductive lines; and
a second sub-spacer disposed between the first sub-spacer and each of the third sub-spacers.

5. The semiconductor device of claim 4, wherein each of the first sub-spacer and the third sub-spacer includes silicon nitride, and the second sub-spacer includes silicon oxide.

6. The semiconductor device of claim 1, wherein each of the nano sheets includes:
first and second doped regions horizontally spaced apart from each other, and
a channel formed between the first doped region and the second doped region.

7. The semiconductor device of claim 1, further comprising:
first contact nodes formed between the first edges of the nano sheets and the vertical conductive lines; and
second contact nodes formed between the second edges of the nano sheets and the data storage elements.

8. The semiconductor device of claim 7, wherein each of the first and second contact nodes includes a selective epitaxial growth layer.

9. The semiconductor device of claim 7, wherein each of the first and second contact nodes includes a doped silicon epitaxial layer.

10. The semiconductor device of claim 1, wherein each of the nano sheets includes:
a narrow sheet coupled to a corresponding one of the vertical conductive lines; and
a wide sheet coupled to a corresponding one of the data storage elements and having a thickness that gradually increases from the narrow sheet toward the corresponding one of the data storage elements.

11. The semiconductor device of claim 1, wherein each of the nano sheets includes monocrystalline silicon, an oxide semiconductor material, a two-dimensional material, or a combination thereof.

12. A method for fabricating a semiconductor device, the method comprising:
forming a stopper layer over a substrate;
forming horizontal and vertical arrangements of narrow sheets over the stopper layer;
forming first spacers surrounding first portions of the narrow sheets in the horizontal arrangement;
forming horizontal conductive lines surrounding second portions of the narrow sheets in the horizontal arrangement;
forming second spacers surrounding third portions of the narrow sheets in the horizontal arrangement;
forming supporters between the narrow sheets in the horizontal arrangement;
recessing the narrow sheets in the horizontal arrangement and forming pillar-shaped openings vertically oriented between the supporters; and
forming vertical conductive lines in the pillar-shaped openings.

13. The method of claim 12, wherein each of the vertical conductive lines is self-aligned with the supporters and coupled to a corresponding one of the recessed narrow sheets.

14. The method of claim 12, wherein each of the supporters includes a low-k material, silicon carbon oxide, silicon nitride, an air gap, or a combination thereof.

15. The method of claim 12, wherein:
each of the first spacers is formed to have a single-layer structure, and
each of the second spacers is formed to have a multi-layer structure.

16. The method of claim 15, wherein the multi-layer structure of each of the second spacers includes:
a first sub-spacer contacting a corresponding one of the horizontal conductive lines and surrounding a corresponding one of the third portions of the nano sheets;
a pair of second sub-spacers contacting the first sub-spacer and a corresponding one of the vertical conductive lines and;
a third sub-spacer disposed between the first sub-spacer and each of the second sub-spacers and disposed between the narrow sheets in the vertical arrangement; and
a fourth sub-spacer disposed between the first sub-spacer and each of the second sub-spacers and disposed between the narrow sheets in the horizontal arrangement.

17. The method of claim 16, wherein each of the first and second sub-spacers includes silicon nitride, and the third and fourth sub-spacers each include silicon oxide.

18. The method of claim 12, further comprising before the forming of the vertical conductive lines:
selectively forming first contact nodes from the third portions of the narrow sheets; and
forming ohmic contact layers on the first contact nodes.

19. The method of claim 12, wherein each of the horizontal conductive lines include a gate-all-around (GAA) structure surrounding the narrow sheets in the horizontal arrangement.

20. The method of claim 12, wherein the forming of the horizontal and vertical arrangements of the narrow sheets over the stopper layer includes:
forming horizontal and vertical arrangements of nano sheet target layers over the stopper layer; and
selectively recessing first portions of the nano sheet target layers to form the horizontal and vertical arrangements of the narrow sheets.

21. The method of claim 20, further comprising after the forming of the vertical conductive lines:
selectively recessing second portions of the nano sheet target layers to form horizontal and vertical arrangements of wide sheets;
selectively forming second contact nodes from side surfaces of each of the wide sheets; and
forming data storage devices each coupled to a corresponding one of the second contact nodes.
